(19) United States
(12) Patent Application Publication
(10) Pub. No.: US 2010/0078724 A1
(43) Pub. Date: Apr. 1, 2010

(54) TRANSISTOR-TYPE PROTECTION DEVICE, SEMICONDUCTOR INTEGRATED CIRCUIT, AND MANUFACTURING METHOD OF THE SAME

(75) Inventors: Tsutomu Imoto, Kanagawa (JP); Kouzou Mawatari, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/568,814

(22) Filed: Sep. 29, 2009

(30) Foreign Application Priority Data
Sep. 30, 2008 (JP) 2008-255556

(51) Int. Cl. H01L 29/78; H01L 29/72; H01L 21/04

(52) U.S. Cl. 257/355; 257/565; 438/142; 257/173; 438/309; 257/E29.255; 257/E29.173; 257/E21.04

(57) ABSTRACT

A transistor-type protection device includes: a semiconductor substrate; a well including a first-conductivity-type semiconductor formed in the semiconductor substrate; a source region including a second-conductivity-type semiconductor formed in the well; a gate electrode formed above the well via a gate insulating film at one side of the source region; a drain region including the second-conductivity-type semiconductor formed within the well apart at one side of the gate electrode; and a resistive breakdown region including a second-conductivity-type semiconductor region in contact with the drain region at a predetermined distance apart from the well part immediately below the gate electrode, wherein a metallurgical junction form and a impurity concentration profile of the resistive breakdown region are determined so that a region not depleted at application of a drain bias when junction breakdown occurs in the drain region or the resistive breakdown region may remain in the resistive breakdown region.

### BACKGROUND OF THE INVENTION

1. Field of the Invention

The present invention relates to a transistor-type protection device that can be turned on and remove noise when noise at a predetermined or higher level is superimposed on wiring of a connected circuit. Further, the present invention relates to a semiconductor integrated circuit in which the transistor-type protection device and a circuit to be protected are integrated on the same substrate, and a manufacturing method of the same.

2. Background Art

Generally, a semiconductor integrated circuit includes a protection circuit for electrostatic discharge (ESD) for protecting an internal circuit from static electricity entering from an external terminal.

The protection circuit connects an ESD protection device between wires where static electricity tends to be superimposed like between the power supply line and the GND line of the internal circuit.

As the ESD protection device, typically, a GGMOS (Gate-Grounded MOSFET) using a MOSFET forming the internal circuit or thyristor is used.

An example of the protection device using a GGMOS is disclosed in JP-A-2002-9281. Further, an example of the protection device using a thyristor is disclosed in M. P. J. Mergens et al., “Diode-Triggered SCR (DTSCR) for RF-ESD Protection of BICMOS SiGe HBTs and CMOS Ultra-Thin Gate Oxides”, in IEDM' 03 Tech. Digest, pp. 21.3.1-21.3.4, 2003.

An advantage of using a thyristor as the protection device is that the on-resistance is low. Accordingly, the thyristor is suitable for protection of small low-withstand-voltage MOSFET. Further, the thyristor is suitable for flowing large current because it can secure a large sectional area of current path.

However, the thyristor has a disadvantage of having a high trigger voltage. If the trigger voltage is high, the internal circuit is broken before the thyristor is turned on.

On this account, various proposals have been made for reducing the trigger voltage.

For example, M. P. J. Mergens et al. discloses an example of a technology using forward current of PN junction. If the technology is applied, the trigger voltage and the hold voltage can be controlled by the number of diodes and the design of the protection device is easy.

However, in the technology disclosed in M. P. J. Mergens et al., the diodes are constantly biased forward, and the statistic leak current is large. The leak current is sensitive to the device temperature and rapidly increases with rise in the device temperature.

Further, in the technology disclosed in M. P. J. Mergens et al., if the number of diodes is reduced for obtainment of the low trigger voltage, the leak current is increased. Accordingly, it may be impossible to use the technology for the application with severe restrictions on power consumption.

On the other hand, the protection circuit using a GGMOS is formed with elongated wiring within the integrated circuit (IC) between the power supply voltage line and the GND line where electrostatistic noise tends to be superimposed as shown in FIG. 1 of JP-A-2002-9281. Here, each of a PMOS transistor and an NMOS transistor of the same type as the inverter of the internal circuit has a GGMOS configuration and series-connected between the VDD line and the GND line.

In FIGS. 3 and 14 of JP-A-2002-9281, sectional structure diagrams of a GGMOSFET are shown.

According to the description of JP-A-2002-9281, there is a low-impurity-concentration semiconductor region led out to the outside of a side wall spacer from a gate electrode in a gate length direction. In JP-A-2002-9281, signs “(7b,8b)” indicate the low-impurity-concentration semiconductor region. The low-impurity-concentration semiconductor region is formed to be a non-silicide region.

According to the description of JP-A-2002-9281, if the low-impurity-concentration semiconductor region is non-silicided, the higher diffusion resistance than that in the case where a high-impurity-concentration semiconductor region is non-silicided is obtained. When a carrier path is secured by the high diffusion resistance, a current path S1 is produced from the LDD end (low-impurity-concentration semiconductor region end) to the source side. Then, the current beyond the flow in the current path S1 is allowed to flow in a new current path S2 starting from a drain region at high impurity concentration to the source side. Thereby, current is distributed and the resistance to electrostatic breakdown of the GGMOS is improved.

### SUMMARY OF THE INVENTION

In the MOS transistor-type protection device disclosed in the above described JP-A-2002-9281, an N-type impurity region (resistive breakdown region) functioning as a resistance layer when the device itself causes junction breakdown overlaps with the gate electrode on a pattern. Accordingly, there are many restrictions on the drain withstand voltage and it is difficult to realize the higher withstand voltage.

More specifically, in the structure JP-A-2002-9281, the drain withstand voltage is restricted by all of the punch-through withstand voltage between the source and the drain, the junction withstand voltage between the drain and the well, and the insulating film withstand voltage between the gate and the drain. Accordingly, it is very difficult to set the drain withstand voltage having an appropriate amplitude for the withstand voltage of the internal circuit to be protected by the MOS transistor-type protection device.

In the protection device disclosed in JP-A-2002-9281, a resistive breakdown region is formed by two low-concentration impurity regions and a high-concentration impurity region between them as a whole. However, the high-concentration impurity region is silicided, and the resistance value varies to some degree in the part. Further, the part on the high-concentration impurity region including the drain region is silicided, and the silicided is near breakdown points. Since the heat generation locations are near the silicide layer, it maybe highly possible that defects of breakage of the part and change in the resistance value of the silicide, or the like occur.

Further, when four of the high-concentration impurity regions and the low-concentration impurity regions are alternately formed as in JP-A-2002-9281, the area penalty is great.

Thus, it is desirable to provide a transistor-type protection device for which a turn-on voltage can be freely set optimally for a circuit to be protected with less restrictions on determination of the turn-on voltage (protection voltage) of the protection device.

Further, it is desirable to provide a semiconductor integrated circuit formed by integrating such a transistor-type protection device with the circuit to be protected.

Furthermore, it is desirable to provide a manufacturing method of the semiconductor integrated circuit with suppressed increase in cost to the minimum extent in the manufacture of the integrated circuit.

A transistor-type protection device according to an embodiment of the invention has a semiconductor substrate, a well including a first-conductivity-type semiconductor formed in the semiconductor substrate, and a source region, a gate electrode, a drain region, and a resistive breakdown region formed with respect to the well.

The source region includes a second-conductivity-type semiconductor formed in the well.

The gate electrode is formed above the well via a gate insulating film at one side of the source region.

The drain region includes the second-conductivity-type semiconductor formed within the well apart at one side of the gate electrode.

The resistive breakdown region includes a second-conductivity-type semiconductor region in contact with the drain region at a predetermined distance apart from the well part immediately below the gate electrode.

A metallurgical junction form and an impurity concentration profile of the resistive breakdown region are determined so that a region not depleted at application of a drain bias when junction breakdown occurs in the drain region or the resistive breakdown region may remain in the resistive breakdown region.

According to the configuration, a predetermined drain bias is applied to the drain region with reference to the potential of the source region (the well can be made at the same potential). As the drain bias is made larger, the depleted layer extends in both depth directions from the metallurgical junction location between the drain region and well and between the resistive breakdown region and the well. Then, junction breakdown occurs at a certain bias. The junction breakdown occurs in either of the drain region or the resistive breakdown region.

When junction breakdown once occurs, current flows from the drain region to the source region. Thereby, the well potential rises and PN junction between the well and the drain region is biased forward. Afterwards, a parasitic bipolar transistor with the source region, well, and drain region or resistive breakdown region as an emitter, base, collector, respectively, is turned on.

When the parasitic bipolar transistor is turned on, the impedance between the emitter and the collector rapidly becomes lower and current flows at the well surface side with reduced impedance.

The metallurgical junction form and the impurity concentration profile are determined so that the region not depleted may remain in the resistive breakdown region when the junction breakdown first occurs. Accordingly afterwards, in the process in which the drain bias becomes larger, the resistive breakdown region functions as a resistance layer in the same manner as before. On this account, the carrier path when the next junction breakdown occurs is secured and the points where junction breakdown can occur are distributed in a wide range from the drain region to the leading end of the resistive breakdown region.

The first junction breakdown (here, avalanche breakdown is taken as an example of junction breakdown) is assumed to occur in the drain region.

In this case, emitter current implanted in the parasitic bipolar operation is collected to the resistive breakdown region nearest the emitter (source region). When the device property is snapped back because of the bipolar operation, the drain voltage (collector voltage) becomes lower and the avalanche breakdown becomes weaker in the drain region (collector region). Instead, electrons implanted from the source region are accelerated at the leading end of the resistive breakdown region and cause avalanche breakdown, and the avalanche breakdown becomes stronger at the leading end of the resistive breakdown region.

Since the potential is determined with reference to the source region, the current allowed to flow in the junction part where breakdown has occurred in the resistive breakdown region flows through the resistive breakdown region that functions as a ballast resistance. Accordingly, the potential of the drain region is raised by the amount of voltage drop calculated from the current and the resistance value. Therefore, junction breakdown becomes easier to occur again in the region where the potential is raised, especially in the drain region where the potential becomes the highest. As a result, junction breakdown occurs in both of the leading end of the resistive breakdown region and the drain region.

As a result of dispersion of the junction breakdown points, points where the temperature rise due to current are distributed in a wide range.

In the embodiment, the turn-on voltage at which large current effective for noise removal starts to flow in the protection device because of the bipolar operation is determined depending on the forms of the resistive breakdown region and the drain region and the impurity concentration profile. Therefore, a more versatile and easy-to-use protection device can be realized with reduced restrictions on the turn-on voltage as much as possible.

In the embodiment, the source side end of the resistive breakdown region is at the predetermined distance apart from the well part immediately below the gate electrode. Accordingly, when the turn-on voltage is determined while securing the withstand voltage between the gate and the drain, there is no constriction due to the withstand voltage and the turn-on voltage can be freely designed by just that much.

A transistor-type protection device according to another embodiment of the invention is the same as the above embodiment in having the semiconductor substrate, well, source region, gate electrode, drain region, and resistive breakdown region. However, in this embodiment, a breakdown-facilitated region is further formed within the well. The breakdown-facilitated region includes the first-conductivity-type semiconductor in contact with or close to a part of the resistive breakdown region.

According to the configuration, since the breakdown-facilitated region is in contact with or close to the part of the resistive breakdown region, the sheet resistance of the resistive breakdown region becomes inhomogeneous within the direction in which current flows. The location and the concentration of the breakdown-facilitated region is determined so that junction breakdown occurs in an intended position.

Specifically, when the concentration of the breakdown-facilitated region is made higher than that of the well concentration, the resistive breakdown region becomes easier to cause junction breakdown in the point where the breakdown-facilitated region is formed. Contrary, when the concentration of the breakdown-facilitated region is made lower than that of the well concentration, the resistive breakdown region becomes easier to cause junction breakdown in the points other than the point where the breakdown-facilitated region is formed.

If the breakdown-facilitated region is provided in this manner, junction breakdown occurs in the resistive breakdown region with assistance of the breakdown-facilitated region. Accordingly, if there is no breakdown-facilitated region, the condition for “the region not depleted at the first junction breakdown remains” is relaxed or unnecessary.

Therefore, in this embodiment, junction breakdown occurs in various distributed locations more reliably and easily than in the case where the locations where junction breakdown occurs are specified purely by the metallurgical junction form and the impurity concentration profile of the resistive breakdown region.

The above embodiments are also applied to a bipolar transistor type protection device and an integrated circuit.

A manufacturing method of a semiconductor integrated circuit related to still another embodiment of the invention includes the steps of forming a first well in a circuit region of a semiconductor substrate and forming a first-conductivity-type second well in a protection device region, and forming various impurity regions within the first well and the second well.

The step of forming the various impurity regions has the following two steps.
(1) First Step: a resistive breakdown region including a second-conductivity-type semiconductor is formed in the second well.
(2) Second Step: a first second-conductivity-type high-concentration impurity region in contact with the resistive breakdown region and a second second-conductivity-type high-concentration impurity region at a predetermined distance apart from an end of the resistive breakdown region are simultaneously formed.

At the first step, the resistive breakdown region is formed within the second well under a condition that a metallurgical junction form and an impurity concentration profile with which a region not depleted remains in the resistive breakdown region when a voltage at which junction breakdown occurs in the first high-concentration impurity region or the resistive breakdown region is applied to the first high-concentration impurity region with reference to potentials of the second high-concentration impurity region and the second well. Simultaneously, another impurity region including the second-conductivity-type semiconductor within the first well.

Another manufacturing method of a semiconductor integrated circuit related to still another embodiment of the invention includes the steps of forming a first well in a circuit region of a semiconductor substrate and forming a first-conductivity-type second well in a protection device region, and forming various impurity regions within the first well and the second well.

The step of forming the various impurity regions has the following three steps.
(1) First step: a resistive breakdown region including a second-conductivity-type semiconductor is formed in the second well.
(2) Second Step: a breakdown facilitated region in contact with or close to the resistive breakdown region from a well depth side is formed.
(3) Third Step: a first second-conductivity-type high-concentration impurity region in contact with the resistive breakdown region and a second second-conductivity-type high-concentration impurity region at a predetermined distance apart from an end of the resistive breakdown region are simultaneously formed.

At the second step, the resistive breakdown region is formed within the second well so that a sheet resistance of a region not depleted left in the resistive breakdown region when a voltage at which junction breakdown occurs in the first high-concentration impurity region or the resistive breakdown region is applied to the first high-concentration impurity region with reference to potentials of the second high-concentration impurity region and the second well may take a predetermined value. Simultaneously, another impurity region including the second-conductivity-type semiconductor within the first well.

According to the two manufacturing methods, the resistive impurity region is formed within the second well at the same time with that the existing other impurity region is formed within the first well. The requirements on the resistive impurity region are the same as those in the above embodiments, and the other impurity region formed at the same time maybe selected to fulfill the requirements. It is common that many impurity regions formed under various conditions exist in the semiconductor circuit. Thus, an impurity region meeting the requirements on the resistive impurity region or having the nearest concentration and form is selected as the other impurity region to be simultaneously formed with the resistive breakdown region.

According to the embodiments of the invention, there is provided a transistor-type protection device for which the turn-on voltage can be freely set optimally for a circuit to be protected with less restrictions on determination of the turn-on voltage (protection voltage) of the protection device.

Further, according to the embodiments of the invention, there is provided a semiconductor integrated circuit formed by integrating such a transistor-type protection device with the circuit to be protected.

Furthermore, according to the embodiments of the invention, there is provided a manufacturing method of the semiconductor integrated circuit with suppressed increase in costs to the minimum extent in the manufacture of the integrated circuit.

### BRIEF DESCRIPTION OF THE DRAWINGS

FIGS. 1A and 1B are circuit block diagrams showing an application example of a protection circuit using a protection device related to the first to fourteenth embodiments.

FIG. 2 is a sectional structure diagram of a MOS transistor-type protection device related to the first embodiment.

FIG. 3 is an operational explanatory diagram of the MOS transistor-type protection device related to the first embodiment.

FIGS. 4A and 4B are sectional views in the middle of the manufacturing of the MOS transistor-type protection device related to the first embodiment.

FIGS. 5A and 5B are sectional views of the MOS transistor-type protection device at the steps subsequent to FIG. 4B.

FIG. 6A and 6B are sectional views of the MOS transistor-type protection device at the steps subsequent to FIG. 5B.

FIG. 7 is a sectional view of the MOS transistor-type protection device at the step subsequent to FIG. 6B.

FIG. 8 is a sectional view of a MOS transistor-type protection device as a comparative example.

FIGS. 9A and 9B are graphs of drain voltage-current characteristics showing snapback.

FIG. 10 is an operational explanatory diagram of the MOS transistor-type protection device of the comparative example.

FIGS. 11A and 11B show 2D simulation results on electric field of the comparative example and the embodiment of the invention.

FIGS. 12A and 12B show 2D simulation results on current density of the comparative example and the embodiment of the invention.

FIGS. 13A and 13B show 2D simulation results on power consumption density of the comparative example and the embodiment of the invention.

FIG. 14 shows simulation results of snap back curves.

FIGS. 15A and 15B are graph on which 2D simulation results on surface potential distribution are plotted in the comparative example and the embodiment of the invention.

FIG. 16 is a sectional structure diagram of a MOS transistor-type protection device related to the second embodiment.

FIG. 17 is a sectional structure diagram of a MOS transistor-type protection device related to the third embodiment.

FIG. 18 is a sectional structure diagram of a MOS transistor-type protection device related to the fourth embodiment.

FIGS. 19A, 19B1, and 19B2 are sectional structure diagrams of a MOS transistor-type protection device related to the fifth embodiment.

FIG. 20 is another sectional structure diagram of the MOS transistor-type protection device related to the fifth embodiment.

FIGS. 21A to 21D are sectional views showing modified examples of those in FIGS. 19A and 20.

FIGS. 22A and 22B are a sectional structure diagram and a plan view of a MOS transistor-type protection device related to the sixth embodiment.

FIGS. 23A and 23B are a sectional structure diagram and a plan view of a MOS transistor-type protection device related to a modified example of the sixth embodiment.

FIG. 24 is a sectional structure diagram of a MOS transistor-type protection device related to the seventh embodiment.

FIG. 25 is a sectional structure diagram of a MOS transistor-type protection device related to the eighth embodiment.

FIGS. 26A to 26B2 show other sectional structures of the MOS transistor-type protection device related to the eighth embodiment.

FIG. 27 shows another sectional structure of the MOS transistor-type protection device related to the eighth embodiment.

FIG. 28 shows another sectional structure of the MOS transistor-type protection device related to the eighth embodiment.

FIG. 29 shows another sectional structure of the MOS transistor-type protection device related to the eighth embodiment.

FIG. 30 is a sectional structure diagram of an IC related to the ninth embodiment.

FIGS. 31A and 31B are sectional structure diagrams in the middle of the manufacturing of the IC related to the ninth embodiment.

FIGS. 32A and 32B are IC sectional views at the steps subsequent to FIG. 31B.

FIGS. 33A and 33B are IC sectional views at the steps subsequent to FIG. 32B.

FIGS. 34A and 34B are IC sectional views at the steps subsequent to FIG. 33B.

FIGS. 35A and 35B are IC sectional views at the steps subsequent to FIG. 34B.

FIGS. 36A and 36B are IC sectional views at the steps subsequent to FIG. 35B.

FIGS. 37A and 37B are IC sectional views at the steps subsequent to FIG. 36B.

FIGS. 38A and 38B are IC sectional views at the steps subsequent to FIG. 36B in another case.

FIGS. 39A and 39B are IC sectional views at the steps subsequent to FIG. 37B or 38B.

FIGS. 40A and 40B are IC sectional views at the steps subsequent to FIG. 39B.

FIG. 41 is a sectional structure diagram of an IC related to the tenth embodiment.

FIG. 42 is a sectional structure diagram of an IC related to the eleventh embodiment.

FIG. 43 is a sectional structure diagram of an IC related to the twelfth embodiment.

FIG. 44 is a sectional structure diagram of an IC related to the thirteenth embodiment.

FIGS. 45A and 45B are sectional structure diagrams of an IC related to the fourteenth embodiment.

FIG. 46 is a sectional structure diagram of a MOS transistor-type protection device related to modified example 1.

### DESCRIPTION OF PREFERRED EMBODIMENTS

Hereinafter, embodiments of the invention will be described with reference to the drawings.

The embodiments of the invention will be explained in the following order.

1. First Embodiment (MOS-type: a three-step drain structure shallower toward the gate side, including a manufacturing method and comparison with a comparative example using simulation results)

2. Second Embodiment (MOS-type: an electric field relaxation region is omitted from the drain structure of the first embodiment)

3. Third Embodiment (bipolar type: a gate electrode is omitted from the structure of the first embodiment)

4. Fourth Embodiment (MOS-type: a low-concentration region at the source side is added to the structure of the first embodiment)

5. Fifth Embodiment (MOS-type: a triple-drain structure shallower toward the drain side)

6. Sixth Embodiment (MOS-type: a drain finger structure)

7. Seventh Embodiment (MOS-type: a breakdown-facilitated region is added to the triple-drain structure of the fifth embodiment)

8. Eighth Embodiment (MOS-type: the triple-drain structure of the fifth embodiment is applied to RESERF-type or the like)

9. Ninth to Fourteenth Embodiments (a manufacturing method applied to a MOS-type IC)

10. Modified Examples 1, 2

### First Embodiment

### [Application Example of Protection Circuit]

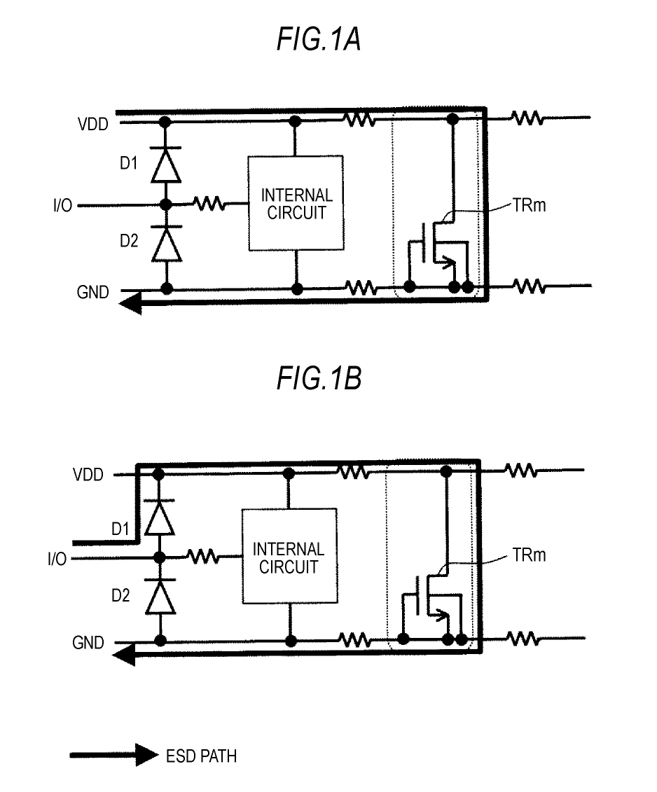

FIGS. 1A and 1B show an application example of a protection circuit using a protection device related to the first to fourteenth embodiments.

The protection circuit (parts surrounded by broken lines) illustrated in FIGS. 1A and 1B is a circuit for protecting an internal circuit and includes one NMOS transistor in this example. The transistor forming the protection circuit may be a PMOS transistor. Note that, the NMOS transistor is desirable for the protection device of the protection circuit because of its current drive performance.

Such a MOS transistor-type protection device is noted by a sign “TRm”.

The protection device may be an external discrete component to an integrated circuit (IC) containing the internal circuit, however, here, the protection circuit and the internal circuit are integrated on a common semiconductor substrate. Accordingly, the configuration shown in FIGS. 1A and 1B corresponds to “semiconductor integrated circuit” of one embodiment of the invention. Further, the MOS transistor-type protection device TRm corresponds to “transistor-type protection device” of one embodiment of the invention.

The MOS transistor-type protection device TRm has a drain connected to a supply line of a power supply voltage VDD and a source connected to a GND line. A gate of the MOS transistor-type protection device TRm is connected to the GND line. Accordingly, the MOS transistor in the connection configuration is called a GG (Gate-Grounded) MOS transistor.

The internal circuit is connected between the supply line of the power supply voltage VDD and the GND line. Accordingly, the internal circuit is driven by the power supply voltage VDD.

In FIGS. 1A and 1B, an input line or output line of signals (hereinafter, collectively referred to as a signal line) from an input/output circuit or input/output terminal noted by a sign “I/O” (not shown) is connected to the internal circuit.

Noise due to static electricity or the like may be superimposed on the signal line. Accordingly, a protection diode D1 with an anode at the signal line side is connected between the signal line and the power supply voltage VDD. Further, a protection diode D2 with an anode at the GND line side is connected between the signal line and the GND line.

Note that GGMOS transistors to which the embodiments of the invention are applied may be added in place of the protection diodes D1, D2.

FIG. 1A is an operational explanatory diagram of the protection circuit when a surge of positive charge enters a power supply terminal.

When a surge of positive charge enters the supply line of the power supply voltage VDD from a power supply terminal or the like (not shown), the potential of the supply line of the power supply voltage VDD rises due to the surge. Before the potential of the supply line of the power supply voltage VDD reaches the breakdown voltage of the intenal circuit, the MOS transistor-type protection device TRm is turned on and turns to a conductive state. Accordingly, the surge escapes to the GND line through the MOS transistor-type protection device TRm.

FIG. 1B is an operational explanatory diagram of the protection circuit when a surge of positive charge enters an I/O terminal.

When a surge of positive charge enters the I/O terminal, the protection diode D1 is biased forward and turned on and allows the surge to flow into the supply line of the power supply voltage VDD. Then, the supply line of the power supply voltage VDD reaches a predetermined potential, the MOS transistor-type protection device TRm is turned on and turns to a conductive state. Accordingly, the surge escapes to the GND line through the MOS transistor-type protection device TRm. For protection of the internal circuit, it is necessary that the protection diode D1 is turned on before the potential exceeds the withstand voltage of input/output of the internal circuit. Further, it is necessary that the MOS transistor-type protection device TRm is turned on before the potential exceeds the (drain) withstand voltage of the transistor of the internal circuit.

Thereby, the internal circuit avoids breakage due to the high voltage.

As described above, the MOS transistor-type protection device TRm is necessary to fulfill the following requirements:

(1) having resistance to electrostatic breakdown not to be broken by the high voltage or large current generated by a surge;

(2) turned on at a voltage higher than the operation voltage of the internal circuit and less than the breakdown voltage of the internal circuit;

(3) having a sufficiently low impedance after turned on; and

(4) having a sufficiently high impedance when not turned on.

### [Device Structure]

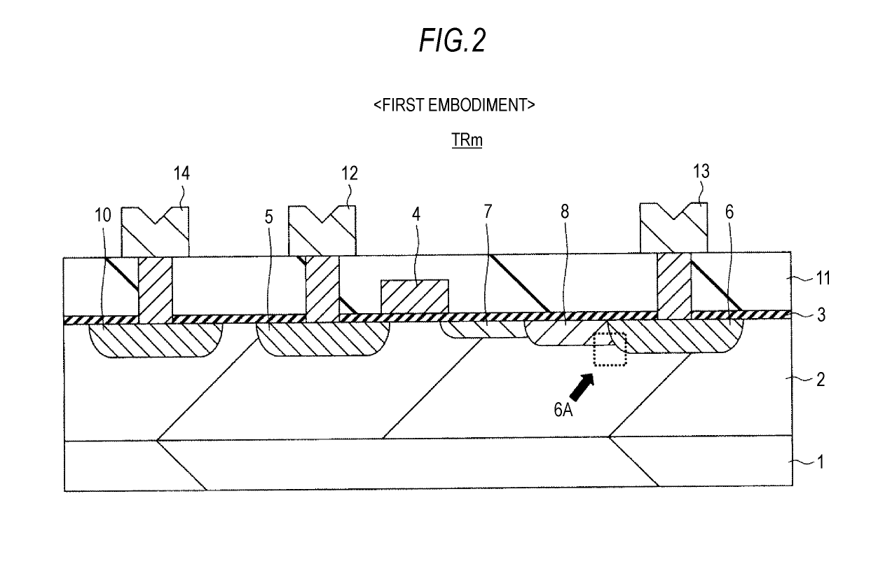

FIG. 2 is a sectional structure diagram of the MOS transistor-type protection device related to the first embodiment.

The MOS transistor-type protection device TRm is formed on a semiconductor substrate 1. The semiconductor substrate 1 is a P-type silicon (crystal plane orientation 100) substrate with an impurity injected at high concentration. A P-type well (hereinafter, referred to as “P-well”) 2 with an impurity injected for obtainment of desired threshold voltages and withstand voltages of the respective parts is formed on the surface side within the semiconductor substrate 1.

On the surface of the P-well 2, a gate insulating film 3 of SiO₂ obtained by thermally oxidizing the surface of the semiconductor substrate 1 is formed.

On the gate insulating film 3, a gate electrode 4 of polysilicon with an N-type or P-type impurity doped is formed.

Although a plan view is not specifically shown, the gate electrode 4 has an elongated finger part. One side in the width direction of the finger part is a source and the other side is a drain.

More specifically, a source region 5 is formed by injecting an N-type impurity at high concentration in the P-well 2 part at the one side of the gate electrode 4 (strictly, the finger part). A drain region 6 is formed by injecting an N-type impurity at high concentration as is the case of the source region 5 in P-well 2 part at the other side of the gate electrode 4 (finger part).

Here, the edge of the source region 5 reaches below the edge of the gate electrode 4 because of lateral diffusion of the impurity. The drain region 6 and the source region 5 partially overlap on a plane pattern.

On the other hand, the drain region 6 is formed at a predetermined distance apart from the gate electrode 4 and does not overlap with the gate electrode 4 on the plane pattern.

An electric field relaxation region 7 is formed between the gate electrode 4 and the drain region 6. The electric field relaxation region 7 is an N-type impurity region that partially overlaps with the gate electrode 4 on the plane pattern as is the case of the source region 5. The electric field relaxation region 7 has concentration of the injected impurity substantially lower than that of the drain region 6, and is formed for the purpose of relaxing the lateral electric field like a so-called LDD region, extension, or the like. It is preferable that the electric field relaxation region 7 is depleted in the entire region in the depth direction at operation as will be described later. Accordingly, no junction breakdown occurs in the electric field relaxation region 7 in this case. In other words, the length of the electric field relaxation region 7 in the isolation direction of the source and the drain and the impurity concentration of the electric field relaxation region 7 are determined so that the junction breakdown may not occur near the gate end.

A resistive breakdown region 8 is formed between the gate electrode 4 and the drain region 6 in contact with the drain region 6 at a predetermined distance apart from the well region part below the gate electrode 4. In this example, the resistive breakdown region 8 is formed between the drain region 6 and the electric field relaxation region 7.

The impurity concentration distribution (impurity concentration profile) of the resistive breakdown region 8 is determined so that the pinch-off voltage of the electric field relaxation region 7 may be higher than the drain breakdown voltage.

Here, the “pinch-off voltage of the resistive breakdown region 8” refers to a voltage applied to the drain region 6 when the drain bias is changed and the depletion layer expands in the depth direction and the electric neutral region disappears (is turned off in the resistive breakdown region 8). The “disappearance (turned off) of the electric neutral region” here means the first occurrence of disappearance in one or plural points of the resistive breakdown region 8.

Further, the “drain breakdown voltage” refers to the voltage of the drain region 6 when the junction breakdown first occurs in the drain region 6 or resistive breakdown region 8 in this example.

This requirement is equivalent to “the (electric neutral) region not depleted at application of the drain bias (e.g., drain voltage) when junction breakdown in the drain region 6 or resistive breakdown region 8 remains in the resistive breakdown region 8”.

When the electric neutral region remains, the resistive breakdown region 8 functions as a resistance layer having appropriate sheet resistance.

The metallurgical junction form including the length, depth, etc. of the resistive breakdown region 8 in the isolation direction of the source and the drain and the impurity concentration profile are determined so that the resistive breakdown region 8 may have a predetermined resistance value with the remaining electric neutral region.

Here, when junction breakdown occurs in the order of the drain region 6 and the resistive breakdown region 8, the upper limit of the “predetermined resistance value” can be defined as below.

As the drain application voltage is raised, junction breakdown occurs in the drain region 6. When the potential rise of the drain region 6 is saturated, the electric neutral region remains in the resistive breakdown region 8 and the predetermined resistance value is held. If the predetermined resistance value is too high, the drain application voltage is further raised and the electric neutral region may disappear before the next junction breakdown occurs at a potential saturated but slightly higher. If so, no junction breakdown occurs afterward in the resistive breakdown region 8. To prevent the situation, the upper limit of the predetermined resistance value is determined according to the metallurgical junction form and the impurity concentration profile of the resistive breakdown region 8.

The lower limit of the “predetermined resistance value” is specified as below when junction breakdown occurs in the order of the drain region 6 and the resistive breakdown region 8.

When junction breakdown first occurs in the drain region 6 as described above, if the drain application voltage is raised, the potential of the drain region 6 is raised little and saturated. On the other hand, when junction breakdown first occurs in the resistive breakdown region 8, voltage drop is caused in the resistive breakdown region 8 due to the immediate drain current and the resistance value over the entire length of the region. When positive noise is applied to the drain side, the potential of the respective impurity regions refers to the potential at the source side. Accordingly, when junction breakdown first occurs in the resistive breakdown region 8, the potential of the drain region 6 is raised with reference to the potential at the source side. Here, if the “predetermined resistance value” of the resistive breakdown region 8 is too small, the amount of voltage drop is too small, and the potential of the drain region 6 is not raised to the potential at which junction breakdown occurs in a part of the drain region 6.

That is, the lower limit of the “predetermined resistance value” is necessary to be equal to or more than a resistance value that is sufficient to cause the next breakdown in the drain region 6 after breakdown occurs first in the resistive breakdown region 8.

Note that the resistance value of the resistive breakdown region 8 is determined by a product of the sheet resistance and the length of the resistive breakdown region 8. These structure parameters are design factors depending on each other, and the optimum value of the resistance value of the resistive breakdown region 8 is not uniquely determined.

Furthermore, the junction depth of the resistive breakdown region 8 is made shallower than the junction depth of the drain region 6. Thereby, a level difference of the metallurgical junction surface is produced near the boundary between the resistive breakdown region 8 and the drain region 6, and a corner curve is formed at the substrate depth side of the drain region 6. Hereinafter, the corner curve is referred to as “convex part 6A”.

In the P-well 2, a well contact region 10 in which a P-type impurity is injected at high concentration is formed.

On the surface of the semiconductor substrate 1, an interlayer insulating film 11 for electric insulation between the semiconductor substrate 1 and upper wiring (not shown) is formed.

On the source region 5, drain region 6, and well contact region 10, a source electrode 12, a drain electrode 13, and a well electrode 14 are formed to bring ohmic contact between the respective N-type impurity regions (diffusion layer) through connection holes penetrating the interlayer film 11.

### [Surge Removal by ESD Operation]

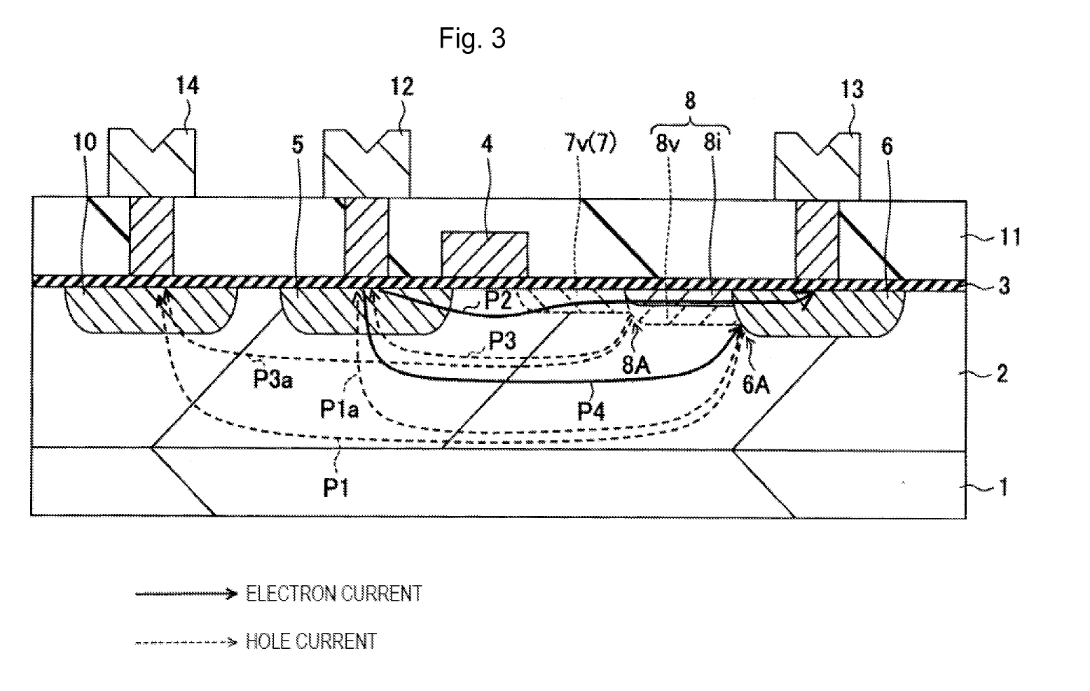

The actions of the respective parts when a surge enters the structure in FIG. 2 will be described using FIG. 3. Here, the operation will be explained by taking the case where junction breakdown occurs in the order of the drain region 6 and the resistive breakdown region 8 as an example.

The case where surge current can be regarded as being equivalent to that when a current source monotonously increasing in a ramp functional fashion with time is connected to the drain of the transistor is considered. By the application of the surge regarded as being equivalent to the connection of the current source (substantially application of drain bias), current flows into the drain electrode 13 of the MOS transistor-type protection device TRm in the off state. When the drain current increases, the drain potential gradually rises.

With the rise of the drain potential, first, the electric field relaxation region 7 is depleted by the depleted layer from the P-well 2. Thereby, the electric field on the gate end is relaxed and junction breakdown at the gate end is avoided.

When the drain voltage further increases, the resistive breakdown region 8 is depleted to some degree. Since the impurity concentration etc. are determined so that the pinch-off voltage of the resistive breakdown region 8 may be higher than the drain breakdown voltage, an electric neutral region 8i remains in the resistive breakdown region 8. In FIG. 3, the depleted layer at the substrate depth side of the resistive breakdown region 8 is denoted by a sign “8v”.

In this operation example, the case where the impurity distribution is determined so that the electric field may be concentrated on the corner curve (hereinafter, referred to as the convex part 6A) of the drain region and first avalanche breakdown (junction breakdown) may occur here will be explained.

Hole current generated by the avalanche breakdown flows in the well along a path P1, and is taken out from the well electrode 14. Simultaneously, the hole current flows in the resistance component in the P-well 2 and the well potential is raised.

The PN junction between the source region 5 and the P-well 2 is biased forward by the raised well potential. Accordingly, electrons are implanted from the source region 5 into the P-well 2, the bipolar operation is started, the drain voltage is reduced, and snapback is observed. Since the drain voltage becomes lower, the collisional ionization in the convex part 6A due to avalanche breakdown becomes relatively weaker.

On the other hand, the implanted electron current flows along a path P2 as the shortest path from the source region 5 to the drain region 6, passes through the resistive breakdown region 8 and the drain region 6, and is taken out from the drain electrode 13. Thereby, a potential gradient is produced within the resistive breakdown region 8. Simultaneously, the electrons passing through the path P2 are accelerated by a high electric field of the convex part 8A and cause collisional ionization, and the avalanche breakdown in the convex part 8A becomes relatively stronger. The hole current generated in the convex part 8A mainly flows through a path P3 into the source region 5, and part of the current passes through a path P3a and is taken out from the well electrode 14.

When the surge current further increases, the potential of the drain region 6 rises again because of the voltage drop generated in the resistive breakdown region 8 due to the current passing through the path P2. As a result, a critical electric field of avalanche breakdown is reached in the convex part 6A of the drain region 6 where the electric field is concentrated, and junction breakdown (avalanche breakdown) becomes stronger again in the convex part 6A.

The hole current generated by the junction breakdown that has been stronger again in the convex part 6A flows around the resistive breakdown region 8 at the high potential downward to the P-well 2 at the low potential, passes through a path P1a, and is mainly taken out from the source electrode 12. As a result, a potential gradient along the path P1a is generated in the deep region of the P-well 2. The electron current implanted from the source region 5 is drawn into the potential and electron current along a path P4 is formed.

In the series of process, the first heat generation is concentrated near the convex part 6A where the first junction breakdown occurs and the current and the electric field are concentrated. Then, the electron current in the path P2 increases, and the center of heat generation moves to the convex part 8A.

However, before breakage occurs in the convex part 8A, the avalanche breakdown becomes stronger again in the convex part 6A as a part of another drain region 6 apart from the convex part 8A. As a result, the heat generation region in the high current range is distributed into three regions of the convex part 8A, the convex part 6A, and the electric neutral region 8i.

Further, the electron current passing through the path P4 and flowing into the drain region 6 broadly flows on the bottom surface of the drain region 6 because of the potential gradient spreading from the resistive breakdown region 8, and the concentration of current density is relaxed.

As a result, power consumption of ESD surge is distributed in a wide range from the resistive breakdown region 8 to the bottom surface of the drain region 6, the local heat generation is relaxed and ESD breakage of the device is avoided to the higher surge current.

When the impurity concentration is determined so that the first junction breakdown may occur in the convex part 8A, the hole current generated by the avalanche breakdown flows in the well along a path P3a, and is taken out from the well electrode 14. Simultaneously, the hole current flows in the resistance component in the P-well 2, and the well potential rises.

Then, the operation is performed in the same manner as the above description starting from the sentence “The PN junction between the source region 5 and the P-well 2 is biased forward by the raised well potential”.

### [Manufacturing Method]

Next, a method of fabricating the MOS transistor-type protection device TRm will be explained with reference to FIGS. 4A to 7 and FIG. 2.

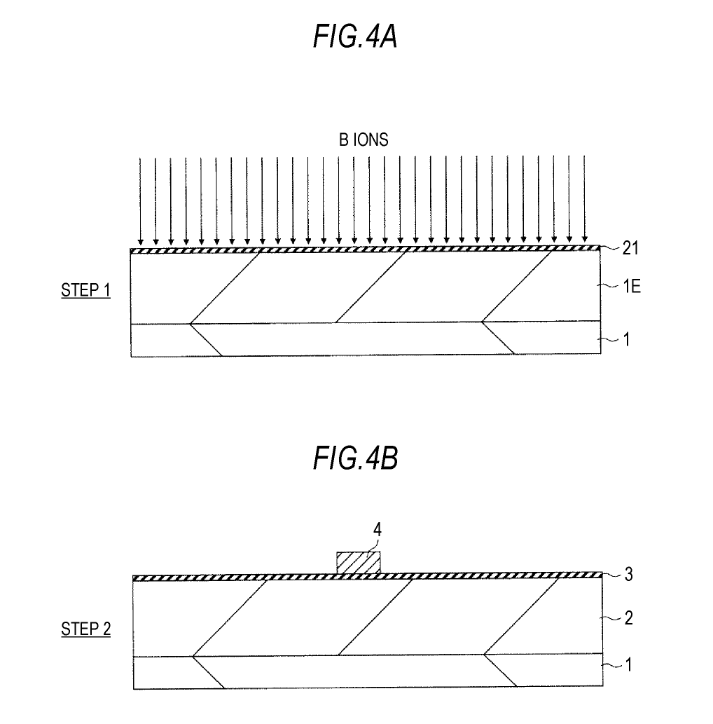

At step 1 in FIG. 4A, in order to form the P-well 2 on the semiconductor substrate 1 of high impurity-concentration P-type silicon, a low-concentration P-type silicon layer is epitaxially grown. The impurity concentration of the semiconductor substrate 1 is equal to or more than 1E19 [cm⁻³], for example, and the impurity concentration of the epitaxial growth layer 1E is equal to or more than 1E15 [cm⁻³], for example.

Subsequently, the surface of the semiconductor substrate 1 is thermally oxidized and a sacrifice oxide film 21 used as a through film for ion implantation is formed.

Then, boron (B) ions are implanted into the semiconductor substrate 1 through the sacrifice oxide film 21, activation annealing is performed thereon, and the P-well 2 of P-type semiconductor is formed. The amount of doze and implantation energy of boron (B) ions are determined so that a desired drain withstand voltage, sheet resistance of the P-well 2, and threshold voltage of the MOSFET formed on the same substrate may be obtained.

Next, at step 2 in FIG. 4B, the sacrifice oxide film 21 is removed by etching using a fluorine solution, and then, the surface of the semiconductor substrate 1 is thermally oxidized again and the gate insulating film 3 is formed. The thickness of the silicon oxide film as the gate insulating film 3 is determined so that a desired gate withstand voltage and threshold voltage may be obtained in the MOSFET formed on the same substrate.

Subsequently, a polysilicon layer (not shown) is deposited on the gate insulating film 3 using thermal CVD, and phosphorus (P) ions are ion-implanted at high concentration into the polysilicon layer.

Subsequently, a resist (not shown) is applied to the entire surface of the semiconductor substrate, and then, optical lithography is performed thereon and a gate pattern is transferred to the resist. Then, reactive ion etching is performed using the resist pattern as a mask, and unnecessary parts of the polysilicon layer are removed. Then, the resist is removed by ashing and the gate electrode 4 is obtained.

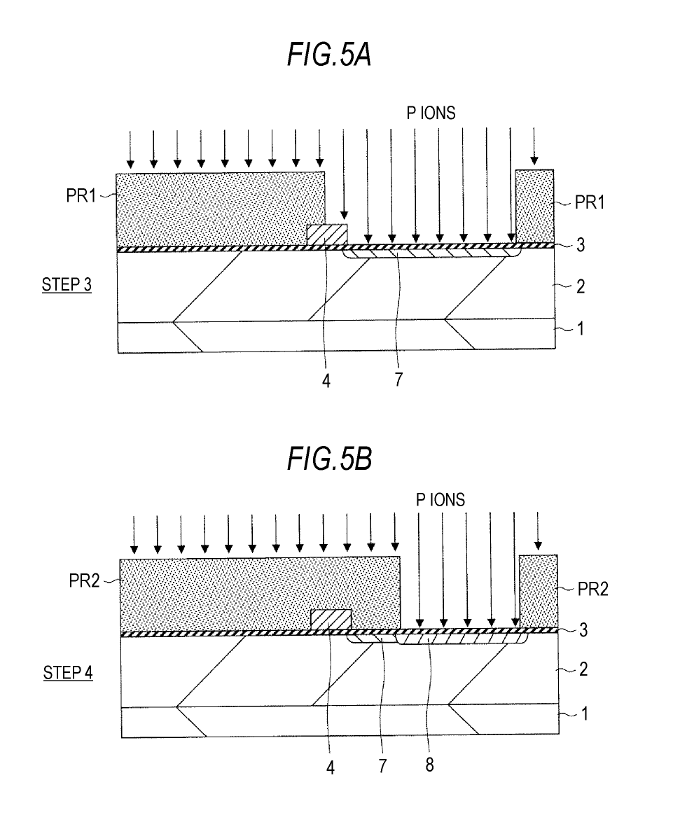

Then, at step 3 in FIG. 5A, the semiconductor substrate 1 is covered by a resist PR1, optical lithography is performed thereon, and the part from the gate electrode 4 to the region to be the drain region 6 (see FIG. 2) is opened. Subsequently, phosphorus (P) ions for formation of the electric field relaxation region 7 are implanted into the surface of the semiconductor substrate 1. The amount of doze and implantation energy of phosphorus (P) may be determined according to the thickness of the gate insulating film 3 as the through film and the desired drain withstand voltage. Then, the resist PR1 is removed by ashing or the like.

Then, at step 4 in FIG. 5B, the semiconductor substrate 1 is covered by a resist PR2, optical lithography is performed thereon, and the part from the resistive breakdown region 8 to the region to be the drain region 6 (see FIG. 2) is opened. Subsequently, phosphorus (P) ions for formation of the resistive breakdown region 8 are implanted into the surface of the semiconductor substrate 1. The amount of doze and implantation energy of phosphorus (P) are determined so that the pinch-off voltage of the resistive breakdown region 8 may be higher than the drain withstand voltage. Then, the resist PR2 is removed by ashing or the like.

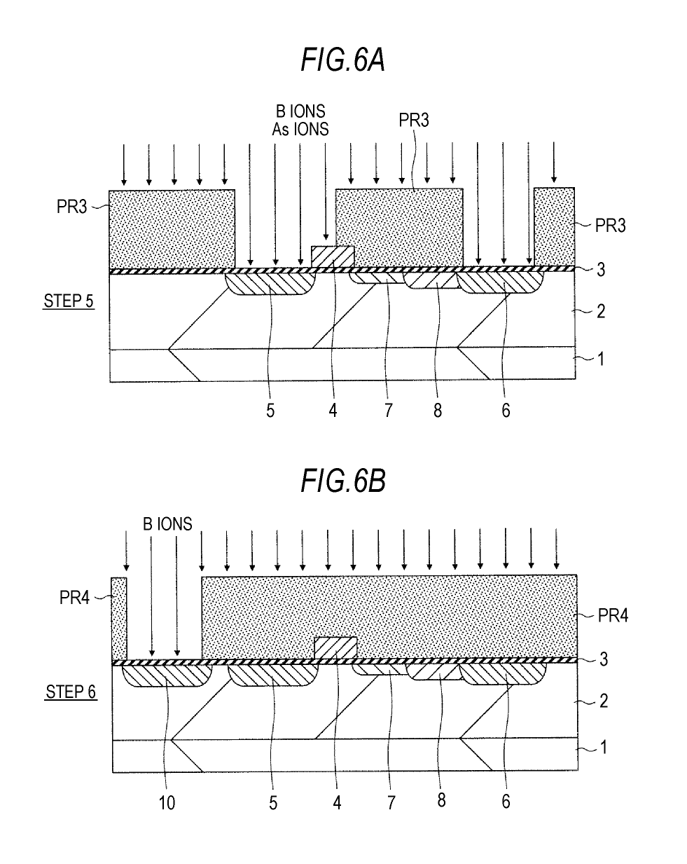

Then, at step 5 in FIG. 6A, the semiconductor substrate 1 is covered by a resist PR3, optical lithography is performed thereon, and the regions of the source region 5 and the drain region 6 are opened. Subsequently, arsenic (As) ions and phosphorus (P) ions are sequentially implanted into the surface of the semiconductor substrate 1. The amounts of doze and implantation energy of the respective ions are determined so that the surface concentration sufficient to form ohmic contact between the source electrode and the drain electrode, which will be formed later, and the junction depth deeper than in the resistive breakdown region 8 may be obtained. Then, the resist PR3 is removed.

Next, at step 6 in FIG. 6B, the semiconductor substrate 1 is covered by a resist PR4, optical lithography is performed thereon, and the region for forming the well contact region 10 is opened. Subsequently, boron (B) ions or boron fluoride (BF₂) ions are implanted into the surface of the semiconductor substrate 1. The amounts of doze and implantation energy are determined so that the surface concentration sufficient to form ohmic contact between the well electrode, which will be formed later, and itself may be obtained. Then, the resist PR4 is removed.

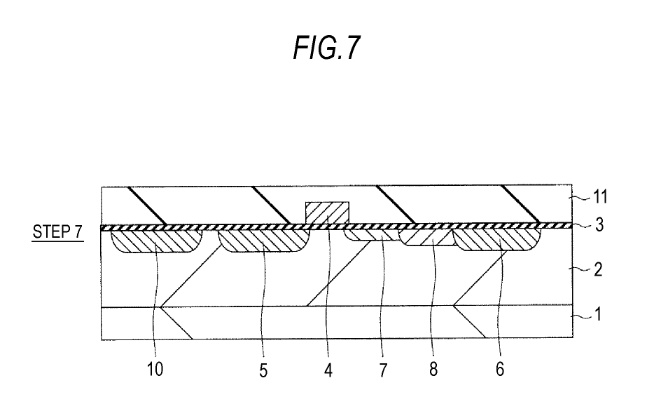

Then, at step 7 in FIG. 7, heat treatment is performed on the substrate and the impurity atoms with the ions implanted at the above described steps are activated.

Subsequently, SiO₂ is thickly deposited on the substrate surface by plasma CVD, the surface is planarized using CMP, and thereby, the interlayer insulating film 11 is obtained.

Subsequently, a resist film (not shown) is formed on the entire surface of the substrate, optical lithography is performed thereon, and a pattern of connection holes to be provided on the source region 5, the drain region 6, and the well contact region 10 is transferred to the resist film. Then, reactive ion etching is performed and the connection holes to the respective parts are formed.

Next, at step 8, a metal such as tungsten is embedded in the connection holes by sputtering and CVD, and a wiring layer of aluminum is formed further thereon. Thereby, as shown in FIG. 2, the source electrode 12, the drain electrode 13, and the well electrode 14 are obtained.

In the above described manner, the MOS transistor-type protection device TRm related to the first embodiment is obtained.

Here, the manufacturing method of the MOS transistor-type protection device TRm that can be used as an N-channel GGMOS is explained.

However, a P-channel protection device maybe fabricated in the same procedure by providing the conductivity types of impurities injected at the respective steps opposite to those in the above explanation.

Further, the start substrate is not necessarily a high-concentration P-type substrate, but may be a high-resistance P-type substrate or N-type substrate.

Note that, in the first embodiment and the other embodiments, the semiconductor substrate 1 is not limited to a substrate made of a semiconductor material of silicon or the like. For example, the case where a substrate made of a material of semiconductor or other than semiconductor is used as a support substrate and a semiconductor layer is formed on the substrate is defined to belong to a category of “semiconductor substrate” in the embodiments of the invention. Accordingly, a substrate for forming a thin-film transistor, an SOI substrate having an SOI layer insulatively isolated from the substrate or the like may be used as the semiconductor substrate.

Next, in the first embodiment, advantages of isolating the resistive breakdown region 8 from the gate electrode 4 at a predetermined distance and advantages related to “resistive breakdown region” will be explained.

For example, as in JP-A-2002-9281, in the case where the N-type impurity region (resistive breakdown region) functioning as a resistance layer when the region itself causes junction breakdown overlaps with the gate electrode 4 on the pattern, there are many restrictions on the drain withstand voltage and it is difficult to realize the higher voltage resistance. That is, in the structure of JP-A-2002-9281, the drain withstand voltage is restricted by all of the punch-through voltage between the source and the drain, the junction withstand voltage between the drain and the well, and the insulating film withstand voltage between the gate and the drain. Accordingly, it is very difficult to set the drain withstand voltage having an appropriate amplitude for the withstand voltage of the internal circuit (FIG. 1) by the MOS transistor-type protection device.

On the other hand, according to the first embodiment, the resistive breakdown region 8 is apart from the well region part immediately below the gate electrode 4, and the degree of freedom of setting of the withstand voltage between the drain and itself is high. Therefore, even in the case where the internal circuit has a high withstand voltage, an ESD protection withstand voltage can be set above that.

Further, since there is no silicide layer, there are less variation factors such that the impurity concentration becomes lower due to heating at silicide formation. Especially, the resistive breakdown region 8 has an optimum range of the predetermined resistance value after breakdown for the impurity concentration profiles of the drain region 6 and the P-well 2. Accordingly, it is necessary to avoid great change in impurity concentration profiles as much as possible, after formation of the resistive breakdown region 8, by sucking out the impurity in the process of silicidation heating or the like, or heating itself.

In JP-A-2002-9281, the resistive breakdown region is formed by two low-concentration impurity regions and a high-concentration impurity region between them as a whole. However, the high-concentration impurity region is silicided, and the resistance value varies to some degree in the part. Further, the part on the high-concentration impurity region including the drain region is silicided, and the silicide is near the breakdown points. Since the heat generation locations are near the silicide layer, it maybe highly possible that defects of breakage of the part and change in the resistance value of the silicide, or the like occur.

In the MOS transistor-type protection device TRm of the first embodiment, the silicide layer causing the defects is not formed.

Further, the area penalty is small compared to the case where four of the high-concentration impurity regions and the low-concentration impurity regions are alternately formed as in JP-A-2002-9281.

Next, advantages over a typical DE-MOSFET will be described. First, the DE-MOSFET will be explained in detail and the advantages provided by the difference between the transistor structure related to the embodiment and itself will be made clear by a simulation.

### Comparative Example 1

### (DE-MOSFET)

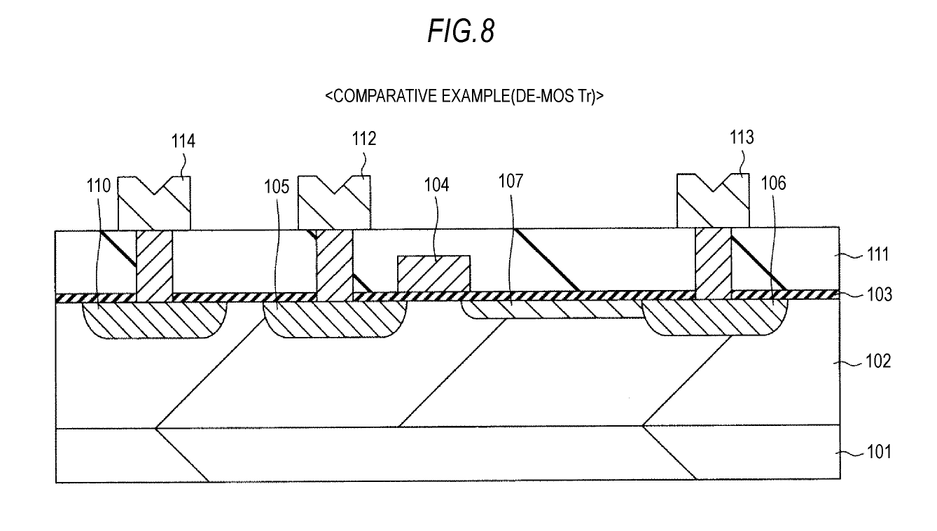

FIG. 8 is a sectional structure diagram of a drain-extended MOS transistor (DE-MOSFET) including an electric field relaxation region for improving the drain withstand voltage.

In the structure shown in FIG. 8, a P-well 102 is formed on a semiconductor substrate 101. On the surface of the semiconductor substrate 101 (strictly, the P-well 102), agate insulating film 103 is formed by thermal oxidation or the like. The P-well 102 has an impurity distribution determined for obtainment of a predetermined threshold voltage and a sheet resistance of the well like the P-well 2 in FIG. 2.

A gate electrode 104 is formed on the gate insulting film 103. One side in the width direction of a finger part forming the gate electrode 104 is the source side and the other side is the drain side.

A source region 105 is formed within the P-well 102 to partially overlap with the one end of the gate electrode 104. Further, a drain region 106 is formed within the P-well 102 apart from the other end of the gate electrode 104. An N-type impurity is injected at high concentration in the source region 105 and the drain region 106.

An N-type electric field relaxation region 107 at the lower concentration than the drain region 106 is formed between the drain region 106 and the well region part immediately below the gate electrode 104. One end of the electric field relaxation region 107 overlaps with the end of the gate electrode 104. In the electric field relaxation region 107, generally, the entire length in the depth direction is depleted at operation like a so-called LDD region, extension, or the like. Accordingly, at application of a drain bias (e.g., drain voltage) when junction breakdown occurs, no electric neutral region remains in the electric field relaxation region 107.

In the P-well 102, a high-concentration P-type well contact region 110 is formed. A well electrode 114, a source electrode 112, and a drain electrode 113 connected to the well contact region 110, the source region 105, and the drain region 106 via plugs or the like are formed as wiring on the interlayer insulating film 11, respectively.

Here, the electric field relaxation region 107 is provided to increase the drain withstand voltage. The electric field relaxation region 107 bears a large part of the electric field between the drain and the gate, and the electric field generated at the gate end is relaxed and the drain voltage causing the breakage at the gate end is raised.

For the electric field relaxation region 107 to bear the sufficient voltage, the concentration of the electric field relaxation region 107 is designed to be sufficiently low and the length is designed to be sufficiently long.

As a result, the drain withstand voltage is substantially determined by the junction withstand voltage between the drain region 106 and the P-well 102.

### [TLP Measurements]

A GGMOS is formed by the DE-MOSFET having the structure shown in FIG. 8, and TLP (Transmission Line Pulsing) measurement is performed thereon.

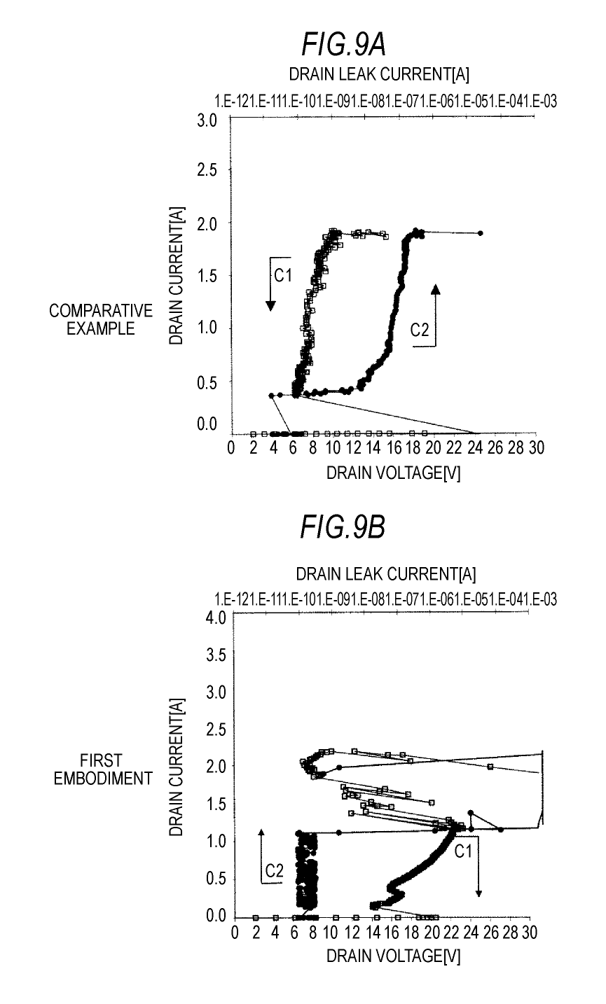

FIG. 9A shows results of TLP measurement of the DE-MOSFET of the comparative example.

A curve C1 shown in FIG. 9A is obtained by providing voltage pulse to the drain electrode 113 in FIG. 8 and measuring a relationship between the transitional drain voltage value and drain current value at time after a predetermined time (e.g., 100 [ns] has elapsed while sequentially increasing the voltage amplitude of the input pulse.

In the curve C1, as the drain voltage is raised, about 0.4 [A] of drain current rapidly starts to flow near 24 [V] due to the above described first junction breakdown, and the drain voltage instantaneously becomes lower to about ¼ of the peak value. The phenomenon that the drain voltage reverts is called “snapback (phenomenon)”. After snapback, the drain voltage and the drain current gradually increase as reflections of increases of pulse height values with respect to each subsequent pulse application.

A curve C2 shown in FIG. 9A shows a results of drain leak current measurement performed alternately with the drain current measurement at obtainment of the curve C1. More specifically, the respective points of the curve C2 are current values plotted with the drain current of the point on the curve C1 measured immediately before as the vertical axis and the drain leak current measured immediately after the measurement of the point on the curve C1 as the horizontal axis.

As shown by the curve C2, the measured drain leak current of the protection device (DE-MOSFET) sequentially increases with the increase in the number of measurements after the first snapback. This suggests that the drain junction breakage progresses at each time of snapback.

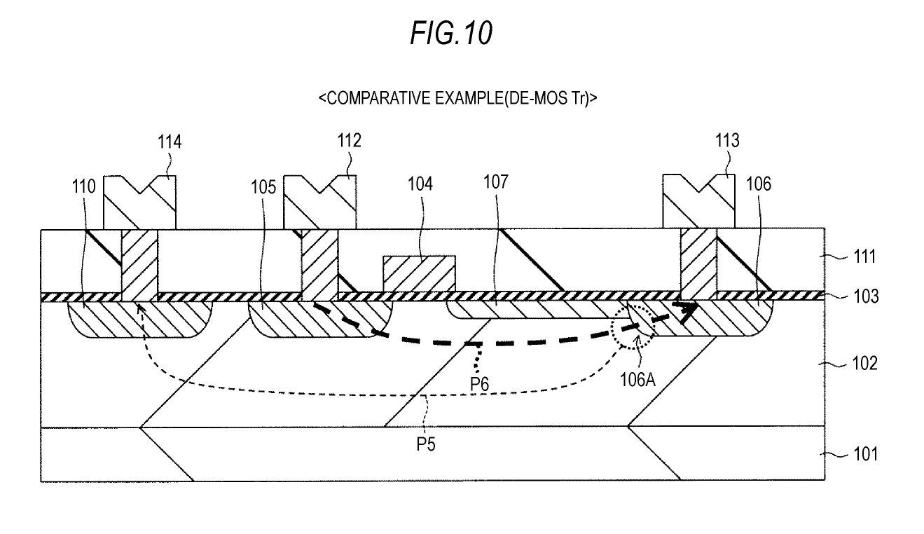

An assumed cause of the above described occurrence of leak will be explained using FIG. 10.

FIG. 10 shows a situation immediately after snapback is induced in the DE-MOSFET in FIG. 8.

First, under the condition that the source electrode 112, the well electrode 114, and the gate electrode 104 are grounded, the current allowed to flow into the drain electrode 113 is increased. Then, the drain voltage rises, depletion of the electric field relaxation region 107 progresses, the entire region is depleted before the drain voltage reaches the drain breakdown voltage. Thereby, the electric field concentrated on the gate end is relaxed, the occurrence of breakage at the gate end is avoided, and thus, the role of the electric field relaxation region is fulfilled.

When the larger drain current is allowed to flow by increasing the drain application voltage, the electric field becomes the maximum in a convex part 106A as a junction part having a curvature at the substrate depth side of the drain region 106. Then, when the drain voltage reaches the drain breakdown voltage, avalanche breakdown starts at some limited points in the convex part 106A on the section of the wafer and the drain region 106 on the wafer flat surface. The points where avalanche breakdown starts typically have spot forms, and called “hot spots”.

Of a pair of a hole and an electron generated by the avalanche breakdown, the electron flows into the drain region 106 and the hole passes through a path P5 and flows from the well contact region 110 into the well electrode 111. Simultaneously, the hole current raises the potential of the P-well 102 because of the resistance of the P-well 102, and the PN junction between the source region 105 and the P-well 102 is biased forward.

When the even larger drain current is allowed to flow by further increasing the drain application voltage, the drain voltage rises and the hole current due to collisional ionization increases. Accordingly, the substrate potential reaches the turn-on voltage of the PN junction before long, and electrons are implanted from the source region 105 into the P-well 102.

The electron current flows from the convex part 106A to the drain region 106 via a path P6 because of the potential gradient formed by diffusion and hole current. When the PN junction between the source and the substrate is turned on, the impedance between the drain and the source becomes lower, the drain voltage is reduced, and snapback is observed. Since the drain voltage becomes lower, no avalanche breakdown may occur at points other than the hot spots, and the breakdown current concentrically flows to the hot spots on the wafer flat surface.

In this way, the electric field and the electron current density are concentrated on the vicinity of the convex part 106A of the drain region immediately after snapback, and thus, the electric energy of the surge is concentrically consumed near the region and generates heat.

It is considered that, because of the concentration of heat generation, crystal defects in the semiconductor substrate 1 multiply and the leak current shown in FIG. 9A increases. Such leak current is prominently generated in the MOSFET at the high drain withstand voltage, and especially problematic in middle to high withstand voltage semiconductor integrated circuits.

FIG. 9B shows an example of results of TLP measurement of the protection device of the embodiment (see FIG. 2).

As shown in the drawing, although the protection device has nearly the same gate width as that of the protection device of the comparative example shown in FIG. 9A, the drain current causing the junction leak increases from 0.4 [A] in the case of the comparative example to 1 [A] or more.

### [Simulation Results and Review]

The transistor structure of the comparative example shown in FIG. 8 and the transistor structure related to the first embodiment shown in FIG. 2 are compared by a device simulation.

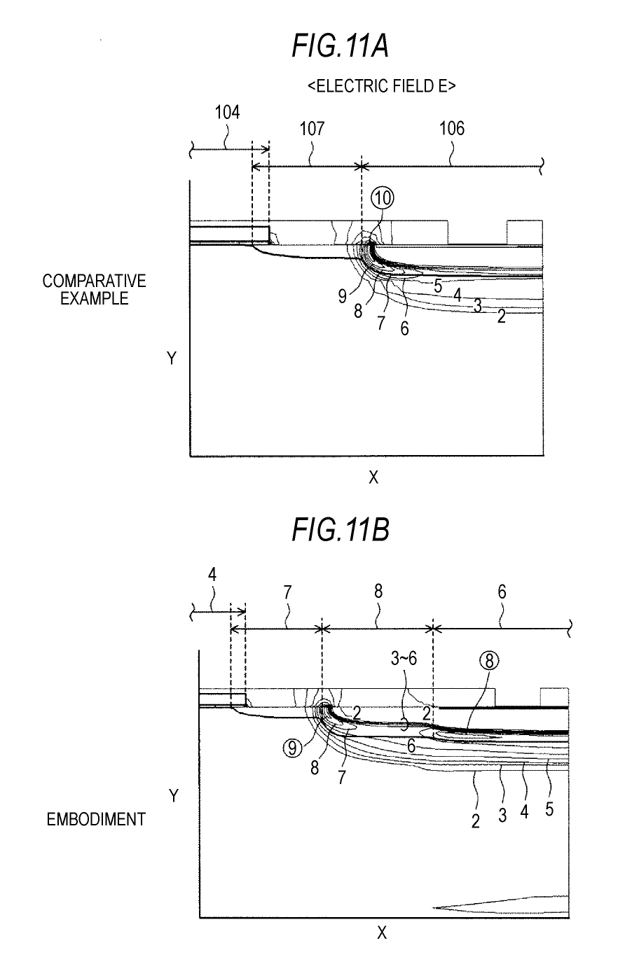

FIGS. 11A to 13B show simulation results of electric field E, current density J, and power consumption density P as a product of them. In the respective drawings, A is a two-dimensional (2D) drawing showing a result for a device structure related to a comparative example and B for a device structure related to the first embodiment of the invention. In the 2D drawing, the horizontal axis X indicates the size in the sectional lateral direction in FIG. 8 or 2, and the vertical axis Y indicates the size in the depth direction. In FIGS. 11A to 13B, numbers of levels indicating the amplitudes of the relative values of electric field E, current density J, and power consumption density P are appropriately attached to level curves as the simulation results of the 2D screen.

Further, in A of the respective drawings, the ranges of the gate electrode 104, the electric field relaxation region 107, and the drain region 106 are shown by the same numerals as those in FIG. 8. In B of the respective drawings, the ranges of the gate electrode 4, the electric field relaxation region 7, the resistive breakdown region 8, and the drain region 6 are shown by the same numerals as those in FIG. 2.

As shown in FIG. 11A, in the comparative example, the electric field E is excessively concentrated on the end of the drain region 106 in contact with the electric field relaxation region 107, and the maximum level is as large as “10”.

On the other hand, in the first embodiment of the invention, as shown in FIG. 11B, there is a concentration location at the maximum level of the electric field E at the end of the resistive breakdown region 8 in contact with the electric field relaxation region 7. At the same time, a concentration location of the electric field E (level “8”) is also formed at the end of the drain region 6 near the resistive breakdown region 8. The maximum level at the breakdown point of the resistive breakdown region 8 is “9”, which is reduced by one level from that of the comparative example.

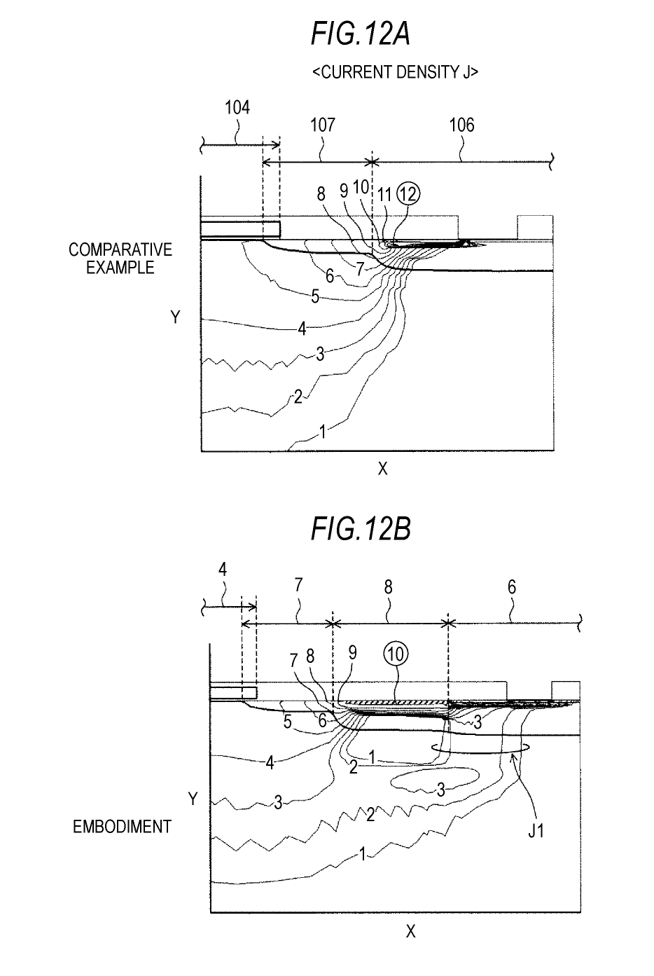

In response to the distribution of the electric field, the current density J shown in FIGS. 12A and 12B is also distributed by the application of the embodiment of the invention.

In the comparative example shown in FIG. 12A, the concentration of the current density falls within a range that is narrow like a point, and its level is as high as “12”.

On the other hand, in the first embodiment of the invention shown in FIG. 12B, a belt-like current concentration location extending in the channel direction is formed at the surface side of the resistive breakdown region 8, and its level is “10”, which is reduced by two levels from that of the comparative example. Further, it is clear that a current path J1 flowing from the end of the drain region 6 to the P-well deep part is newly produced.

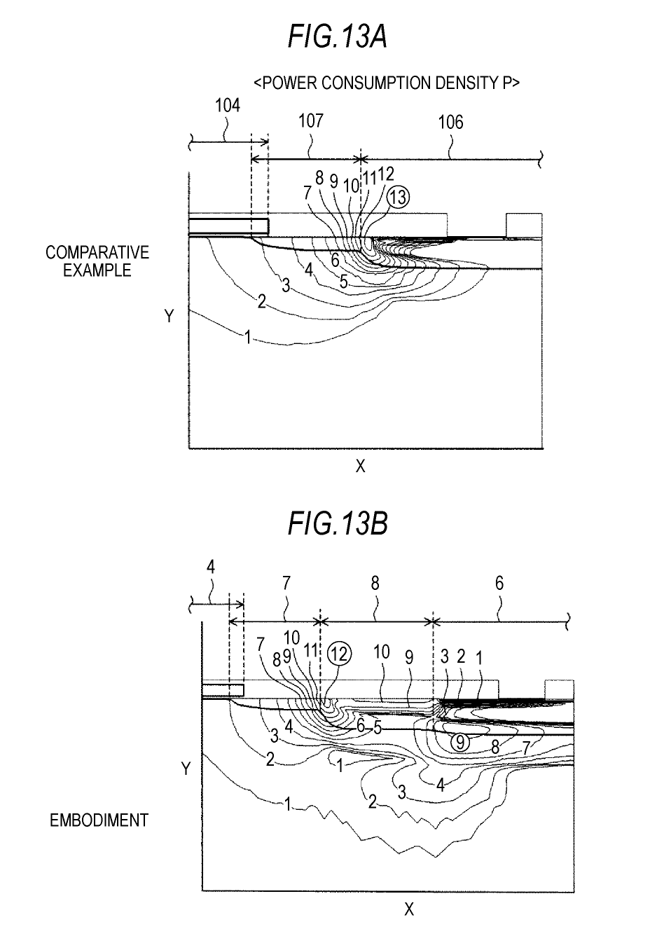

By the above described distribution of the electric field E and distribution of the current density J, the power consumption density P shown in FIGS. 13A and 13B has peaks divided from one point into two points by the application of the embodiment of the invention. Further, the maximum level is reduced from “13” of the comparative example to “12” of the first embodiment.

Accordingly, it is clear that heat generation is suppressed by the application of the embodiment of the invention.

In this simulation, the snapback phenomenon and the surface potential distributions at the phenomenon with respect to four current values have been investigated.

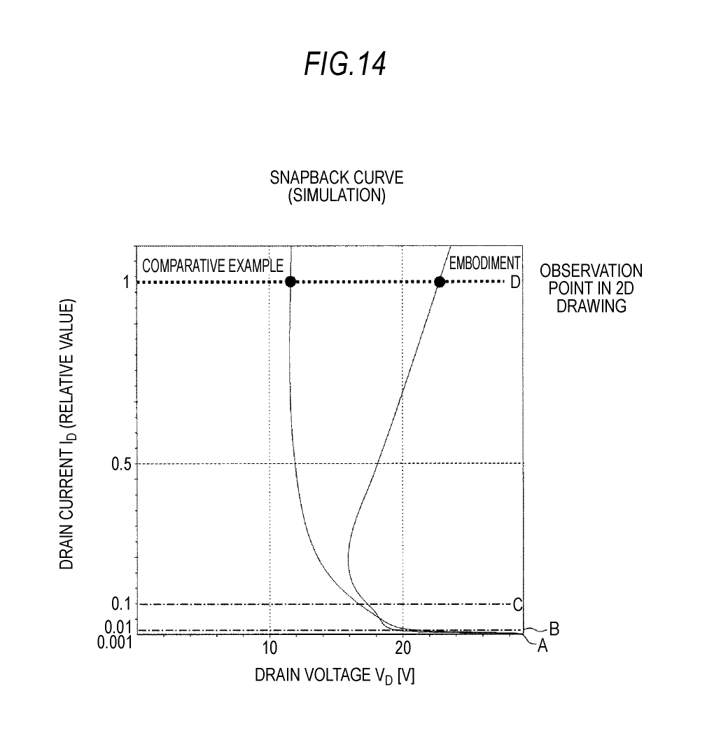

FIG. 14 shows simulation results of snap back. In the simulation, a drain voltage V_{D} when drain current I_{D} is input as a ramp waveform that becomes gradually larger and a surface potential distribution in the X direction thereof are estimated with different structure parameters in the comparative example and the embodiment and compared.

As shown in FIG. 14, in the comparative example, as the drain current I_{D} is raised, the drain voltage V_{D} monotonously becomes lower. On the other hand, in the structure of the embodiment, the drain voltage V_{D} takes the minimum value near the point at which the drain current I_{D} 0.2-times the value at the observation point is allowed to flow. When the drain current I_{D} is further increased, oppositely, the drain voltage V_{D} becomes lower and the rate of the reduction is nearly linear.

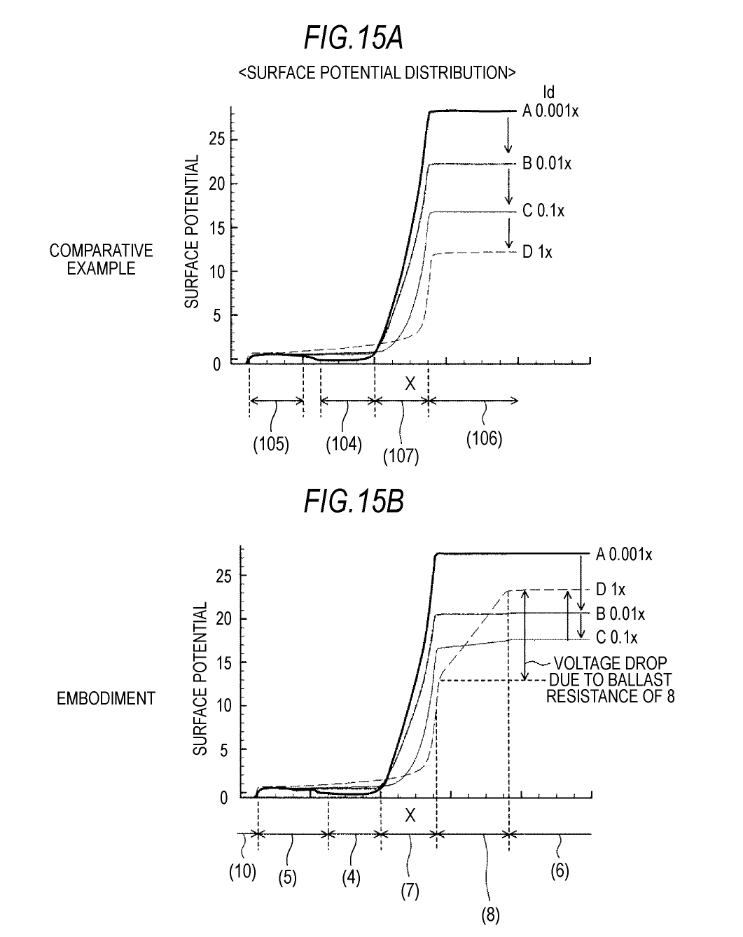

This also clearly appears in the surface potentials of the drain region in the surface potential distributions shown in FIGS. 15A and 15B.

In the comparative example in FIG. 15A, as the drain current I_{D} is increased from curve A to curve D, the drain surface potential also becomes lower.

On the other hand, in the first embodiment of the invention in FIG. 15B, in the transition from the curve C to curve D, the potential relationship is inverted to that in the comparative example. Further, in the curve D when the drain current I_{D} at the observation point is allowed to flow, linear potential rise appears in the channel current direction of the resistive breakdown region 8. This means that the resistive breakdown region 8 has an effect of raising the potential at the drain side with reference to the source side end potential of the resistive breakdown region 8. In other words, the results obviously show that the resistive breakdown region 8 functions as a so-called “ballast resistance” of relaxing excessive concentration of the electric field and the current density by gradually changing the potential in the channel direction.

On the basis of the above described results, the operation in the embodiment will be described as follows in comparison to the comparison examples.
(1) A surge is input to the drain of the protection device. The behavior of the protection device may be regarded as being equivalent to the case where a current source in which current monotonously increases with time is connected to the drain of the protection device according to a certain model.
(2) The drain potential rises due to the current caused by the surge input to the drain, and, at a certain voltage, avalanche breakdown starts to occur from some weak point in the drain width, i.e., a hot spot.
(3) The holes generated in the breakdown point flow as hole current to the substrate contact through the substrate, and raise the substrate potential.
(4) When an amount of the hole current becomes a certain degree, the substrate potential reaches the turn-on voltage of PN junction, and electrons are implanted from the source region into the substrate. The electron current exponentially increases with respect to the substrate bias and the impedance between the source and the drain rapidly becomes lower.
(5) As a result of the reduced impedance, the potential near the breakdown point becomes lower.

### (5-1) Case of Comparison Example

Concurrently, in the comparative example, the breakdown point is close to the silicide at nearly the same potential, and the potential of the breakdown point becomes lower and the potential of the entire silicide region is reduced to the drain breakdown voltage or less over the entire drain width. As a result, any junction breakdown does not occur in the regions other than at the point where breakdown has already occurred, and the breakdown current concentrically flows into the one point (the hot spot) where breakdown has first occurred. Accordingly, here, the local current density becomes extremely high.

Further, in the comparative example, as shown in FIG. 13A, heat generation (power consumption density P) is concentrated on the short part of the drain region. As a result, the silicon of the substrate is thermally damaged in the heat generation concentration location, and crystal defects to be a cause of soft leak are produced.

### (5-2) Case of the Embodiment

On the other hand, in the structure of the embodiment, also the potential of the breakdown point once drops, and the breakdown current concentrically flows there.

However, in the structure of the embodiment, the heat generation location at the high breakdown current density is distributed in a broad region from the resistive breakdown region 8 to the bottom surface of the drain region 6 as shown in FIG. 13B. Accordingly, if the current causing breakage in the comparison example is input, the point is less subject to the damage due to heat generation concentration.

Further, the resistive breakdown region 8 exists between the breakdown point (the leading end of the resistive breakdown region) and the drain region 6 (limited to the drain region 6 if silicided). The resistive breakdown region 8 functions as a ballast resistance as has turned to be clear in FIG. 15B. Accordingly, the breakdown current increases, the voltage breakdown in the resistive breakdown region 8 increases, and consequently, the potential of the drain region 6 turns to increase as shown in FIG. 15B.

As a result, the drain voltage is recovered to a voltage equal to or more than the drain breakdown voltage again, and junction breakdown starts at other points and finally junction breakdown occurs over the entire gate width.

Thereby, the current density around the gate width becomes lower and concentration on one point of surge current is avoided.
(6) Consequently, in the embodiment, crystal defects causing soft leak are not produced and high It2 (secondary breakdown current break current) is obtained.

The above description will be summarized as follows. In the embodiment, first, even when junction breakdown starts at one point, heat generation concentration is distributed and thermal damage in the one point is avoided. During withstanding, the surge current increases and the drain voltage is raised again. Then, the drain breakdown voltage is reached at the other points and junction breakdown starts.

When the surge current further increases, junction breakdown finally occurs over the entire drain width.

In such a process, production of local crystal defects at the end of the drain causing soft leak can be avoided, and breakage of the entire device can be avoided to the higher current (It2) even when the surge current further increases because the concentration of heat generation is distributed.

### 2. Second Embodiment

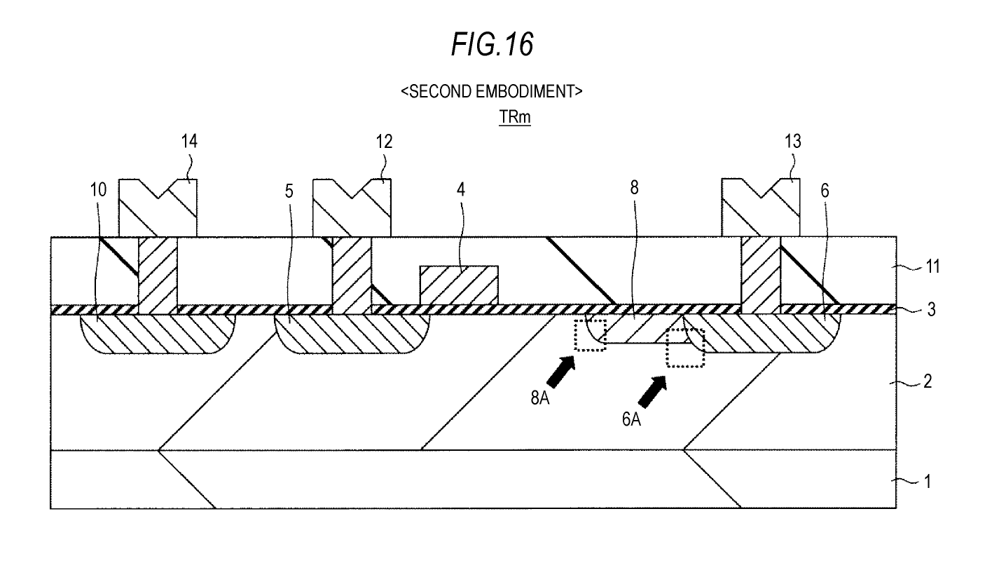

FIG. 16 is a sectional view of a MOS transistor-type protection device TRm related to the second embodiment.

The structure shown in FIG. 16 is a structure formed by removing the electric field relaxation region 7 from the structure in FIG. 2.

In the MOS transistor-type protection device shown in FIG. 16, the resistive breakdown region 8 functions as a ballast resistance when first junction breakdown occurs in the convex part 8A or the convex part 6A as is the case of the first embodiment. Accordingly, an effect that the drain voltage rises oppositely due to the voltage drop of the resistive breakdown region 8 is obtained. As a result, the production of local crystal defects at the end of the drain causing soft leak can be avoided, and breakage of the entire device can be avoided to the higher current (It2) even when the surge current further increases because the concentration of heat generation is distributed.

Further, since the resistive breakdown region 8 is apart from the well region part below the gate electrode 4 at the predetermined distance, the withstand voltage of the protection device can be set without restriction of the withstand voltage between the drain and the gate.

### 3. Third Embodiment

As is clear from the above described operation of the first embodiment, the MOS transistor-type protection device TRm intrinsically performs bipolar transistor operation, and thus, the gate electrode 4 is unnecessary.

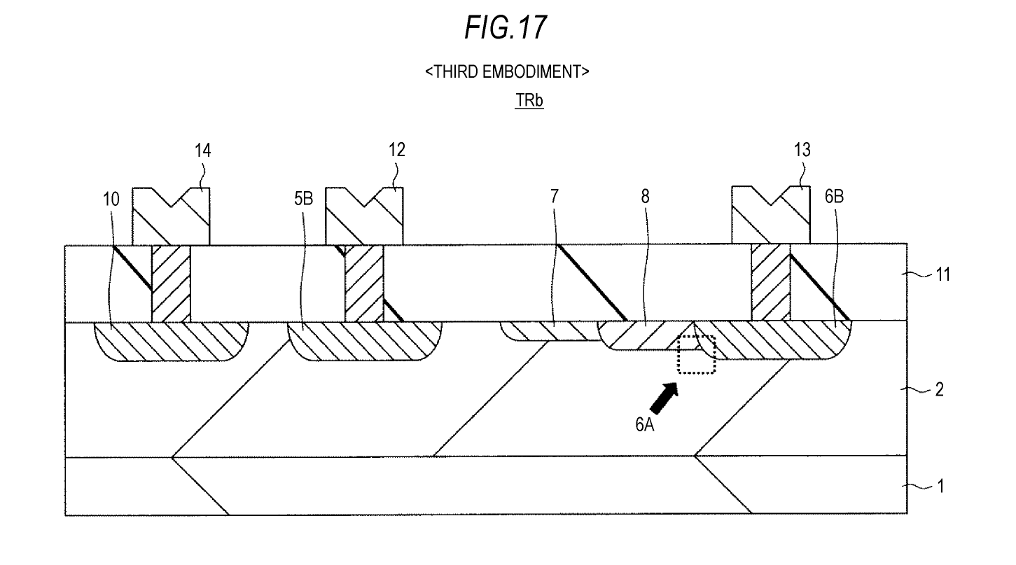

FIG. 17 is a sectional view of a bipolar transistor-type protection device related to the third embodiment.

The structure shown in FIG. 17 is a structure formed by removing the gate electrode 4 and the gate insulating film 3 from the structure in FIG. 2.

The bipolar transistor-type protection device TRb shown in FIG. 17 may be used in place of the MOS transistor-type protection device TRm in FIGS. 1A and 1B.

In FIG. 17, a term “emitter region 5B” is used in place of the source region 5, and a term “collector region 6B” is used in place of the drain region 6. Further, the P-well 2 functions as “base region”, and the well contact region 10 functions as “base contact region”.

The manufacturing method, materials, and other structure parameters may be the same as those in the first embodiment.

According to the MOS transistor-type protection device TRb shown in FIG. 17, the same effect as that in the first embodiment that has been summarized in the second embodiment can be obtained. Without the gate electrode, the restrictions are further relaxed and the withstand voltage as the protection device can be freely determined.

### 4. Fourth Embodiment

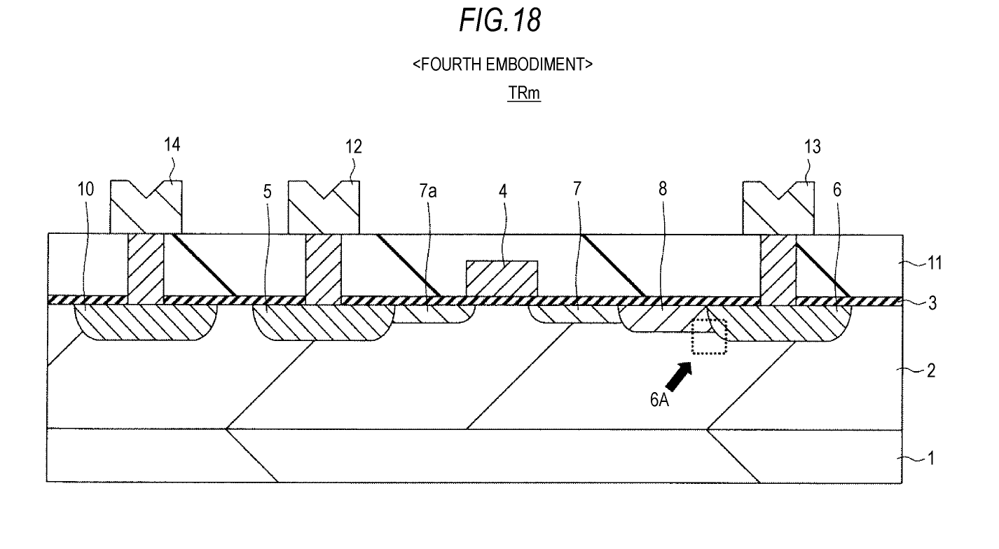

FIG. 18 is a sectional view of a MOS transistor-type protection device TRm related to the fourth embodiment.

The structure shown in FIG. 18 is a structure formed by adding a low-concentration region 7a formed at the same steps as those of the electric field relaxation region 7 between the source region 5 and the gate electrode 4 of the structure in FIG. 2.

By the length of the added low-concentration region 7a in the channel length direction, the on-resistance of the snapback curve can be adjusted to a desired value. In addition, the same effect as that of the first embodiment summarized in the second embodiment can be obtained in the fourth embodiment.

### 5. Fifth Embodiment

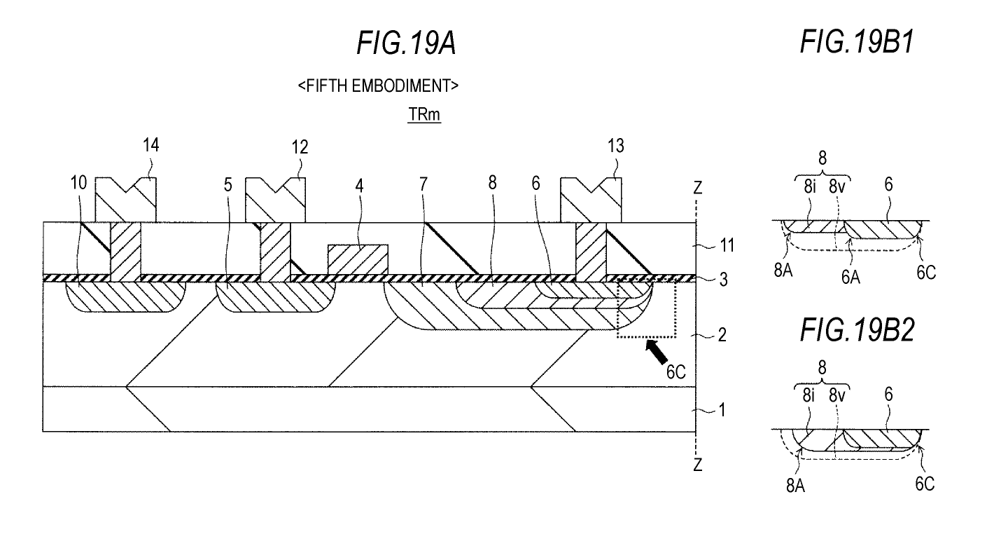

FIG. 19A is a sectional view of a MOS transistor-type protection device TRm related to the fifth embodiment.

The structure shown in FIG. 19A is a structure suitable for the case where the drain region 6 is shallow and it may be impossible to provide a sufficient difference in junction depth between the resistive breakdown region 8 and itself.

The metallurgical junction depth is larger in the order of the drain region 6, the resistive breakdown region 8, and the electric field relaxation region 7. Further, the resistive breakdown region 8 is formed slightly smaller within the electric field relaxation region 7 and the drain region 6 is formed slightly smaller within the resistive breakdown region 8.

Note that the distance from the end of the resistive breakdown region 8 to the end of the electric field relaxation region 7 at the source side is an optimum length for electric field relaxation. Further, the distance from the end of the drain region 6 to the end of the resistive breakdown region 8 at the source side is an optimum length for a ballast resistance.

On the other hand, the opposite end to the source side of the drain region 6, the electric field relaxation region 7, and the resistive breakdown region 8 is a location where another convex part 6C is formed.

FIG. 19B1 shows a state that a part of the resistive breakdown region 8 in the depth direction is depleted at operation.

The state in FIG. 19B1 is that the first breakdown occurs in the convex part 8A or the convex part 6A. For example, if the first breakdown occurs in the convex part 8A, the second breakdown occurs in the convex part 6A or the convex part 6C corresponding to the corner at the opposite substrate depth side. In the convex part 6A and the convex part 6C, breakdown may occur formerly in one of them, and breakdown may occur later in the other.

In either case, when the surface edges are aligned as shown in the drawing, breakdown easily occurs, and this is an advantageous structure for further distribution of heat generation locations.

In place of FIG. 19B1, as shown in FIG. 19B2, the resistive breakdown region 8 may be partially depleted.

The state of FIG. 19B2 shows when breakdown occurs in the convex part 8A or the convex part 6C. For example, if the first breakdown occurs in the convex part 8A, the second breakdown occurs in the convex part 6C corresponding to the corner at the substrate depth side.

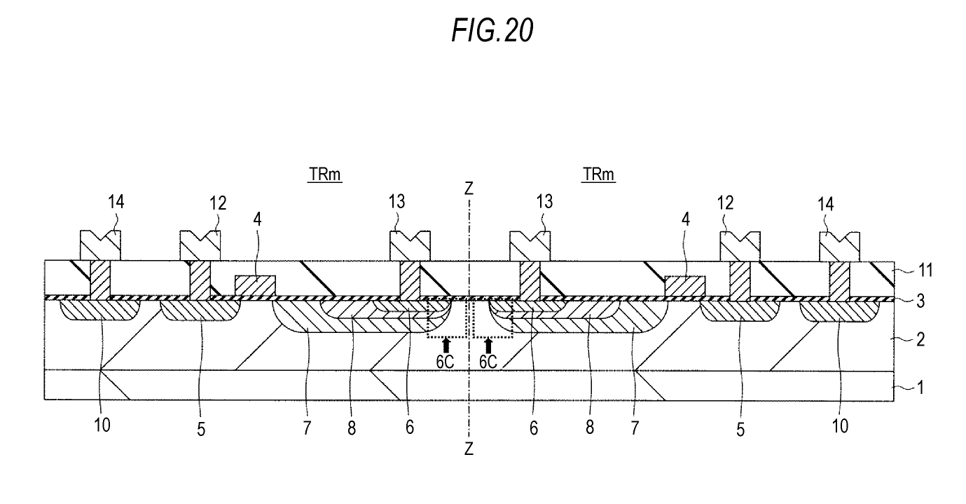

FIG. 20 shows a mirror inversion of the structure in FIG. 19A with respect to the Z-Z line.

Such a structure adopts a multi-finger gate configuration, for example, and is similar to the structure of sharing the drain between two finger parts of MOS transistor-type protection devices TRm or the like. Here, in the multi-finger gate structure, the gate is formed to have multiple fingers (reed shapes), and at least one of the source and the drain is shared between the two adjacent gate fingers.

When the drain is shared, typically, in FIG. 20, a pattern connecting two electric field relaxation regions 7, two resistive breakdown regions 8, and two drain regions 6 on the left and right of the Z-Z axis is adopted. In this case, naturally, no convex part 6C is formed.

It is desirable that the surface edges are aligned for easy breakdown, however, when metallurgical junction is deeper in the resistive breakdown region 8 than in the drain region 6, it is not necessary to align the surface edges of junction at the far side from the gate.

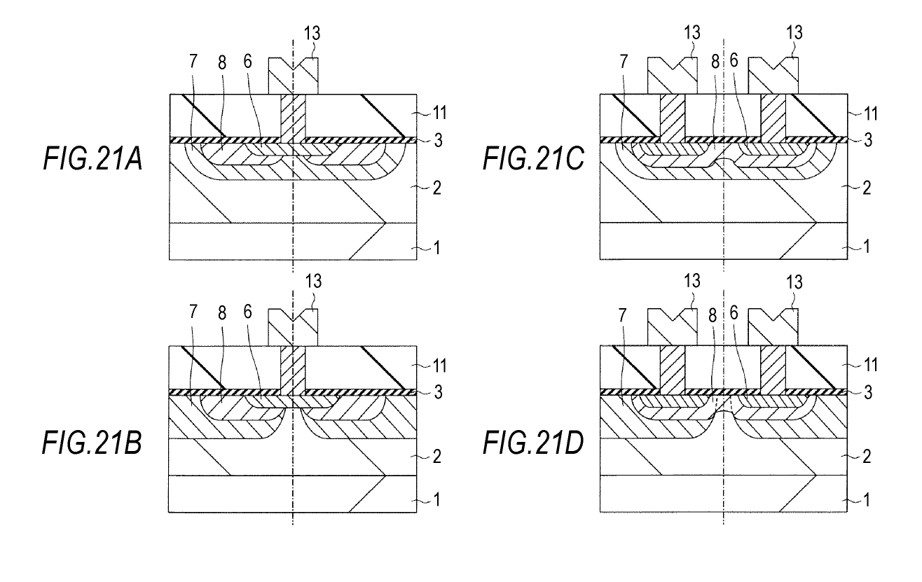

FIGS. 21A to 21D are sectional views showing combinations of junction forms other than those in FIGS. 19A and 20. Here, FIGS. 21A and 21B show a modified example of FIG. 19A and FIG. 21C and FIG. 21D show a modified example of FIG. 20.

As seen from these drawings, below the drain electrode 13, the drain region 6 and the resistive breakdown region 8 may be completely enclosed by the electric field relaxation region 7, or the electric field relaxation region 7 may be isolated to bring a part of the drain region 6 into direct contact with the P-well 2.

The same effect as that in the first embodiment that has been summarized in the second embodiment can be obtained in the fifth embodiment.

### 6. Sixth Embodiment

The sixth embodiment relates to a multi-finger drain structure.

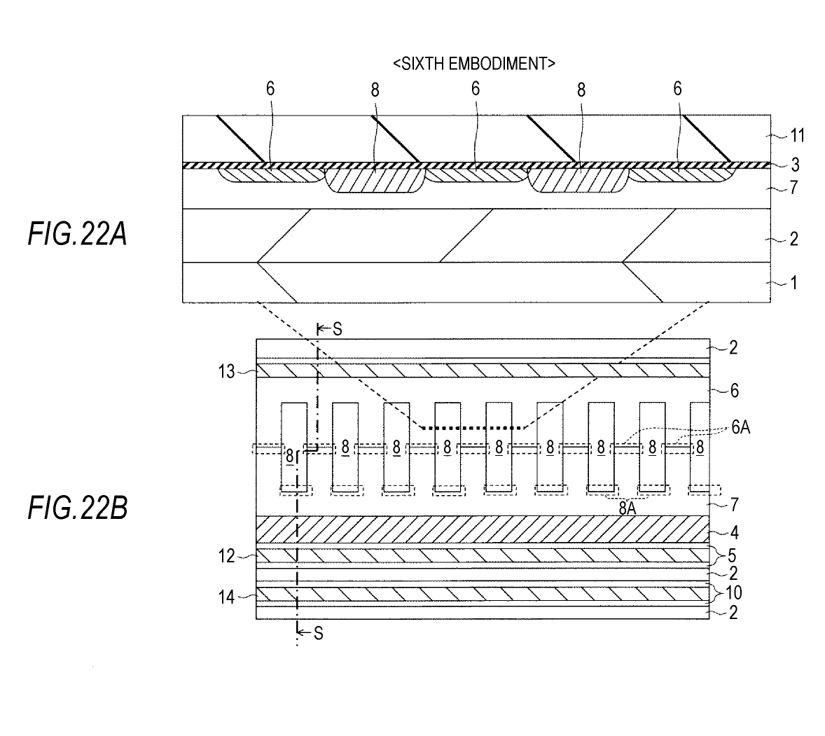

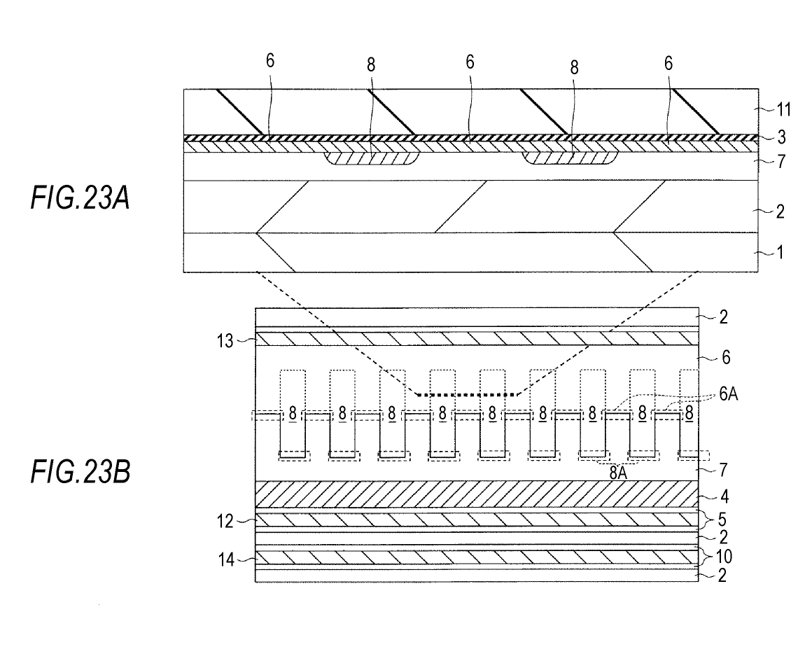

FIGS. 22A to 23B are sectional views and plan views of the multi-finger drain structure. FIGS. 22B and 23B are plan views and corresponding FIGS. 22A and 23A show sections of thick broken lined parts in the plan views.

The same signs are assigned to the configuration having the same function as that of the first embodiment.

In the multi-finger drain structure, as shown in FIGS. 22B and 23B, the gate electrode 4 has a linear shape and the resistive breakdown regions 8 close to the gate electrode 4 are formed to have reed shapes. On the other hand, the drain region 6 is formed at the farther side from the gate electrode 4 than the resistive breakdown region 8.

In the structure shown in FIGS. 22A, the drain region 6 and the resistive breakdown region 8 do not overlap as a pattern as seen in the section thereof. On the other hand, in the structure in FIG. 23B, the drain region 6 overlaps like blankets with the resistive breakdown regions 8 to the half in the length direction.

As described above, the difference between the FIGS. 22A and 22B and FIGS. 23A and 23B is in the difference with or without overlapping between the drain region 6 and the resistive breakdown regions 8, and there is not so much difference between them in intrinsic functions.

In either case, from the edge locations of the resistive breakdown regions 8 and the drain region 6 at the gate electrode 4 side, the edges of the drain region 6 and the edges of the resistive breakdown regions 8 are located at the different levels on the plane pattern. In this regard, the edge location of the drain region 6 is at the greater distance from the gate electrode 4 than the edge location of the resistive breakdown region 8.

From the section shown by S-S line (dashed-dotted line) in FIG. 22B, it is easily understood that the sectional structure is not greatly different from that in FIG. 19A. Note that, in comparison of sectional structures, there are differences in whether the edges of the respective regions are aligned in the convex part 6C or not and the depth relationships between the drain region 6 and the resistive breakdown region 8.

The operation will be briefly explained by taking the case where the first avalanche breakdown occurs at the leading ends (convex parts 6A) of the drain region 6 as an example.

In FIGS. 22B and 23B, first, avalanche breakdown occurs at the leading ends (convex parts 6A) of the drain region 6. The hole current generated there flows from the convex parts 6A of the drain to the well electrode 14, and positively biases the potential of the P-well 2. Thereby, the PN junction between the source region 5 and the P-well 2 is biased forward, electrons are implanted from the source region 5 to the P-well 2, and bipolar operation occurs. As a result, the impedance between the drain and the source becomes lower, the drain potential is reduced, and snapback occurs.

On the other hand, the electrons implanted from the source region 5 are collected to the leading ends (convex parts 8A) of the resistive breakdown regions 8, and flows through the resistive breakdown regions 8 to the drain region 6. Simultaneously, the electrons are accelerated by the high electric field near the convex parts 8A of the resistive breakdown regions and cause avalanche breakdown in the convex parts 8A. Further, electron current produces a potential gradient in the resistive breakdown regions 8, and raises the potential of the drain region 6 again.

Since the drain voltage rises, the avalanche breakdown becomes stronger in the drain region 6 again. As a result, the heat generation region is distributed in a broader region from the leading ends (convex parts 8A) of the resistive breakdown regions 8 to the resistive region 6, further from the leading ends (convex parts 6A) of the drain region 6 to the bottom surface of the drain region 6.

As described above, in the sixth embodiment, the breakdown parts (convex parts 8A) of the leading ends at the gate side of the resistive breakdown regions 8 and the breakdown parts (convex parts 6A) as the edge parts of the drain region 6 between the resistive breakdown regions 8 are alternately and uniformly formed by the effect of the pattern shape. Accordingly, there is an advantage that the heat generation locations are two-dimensionally distributed as intended by the pattern design.

The other basic effects are the same as those in the first embodiment summarized in the second embodiment.

In the case of FIGS. 23A and 23B, compared to the case of FIGS. 22A and 22B, the resistance of the drain region 6 may be set lower and the on-resistance of snapback can be made smaller by that reduced amount.

### 7. Seventh Embodiment

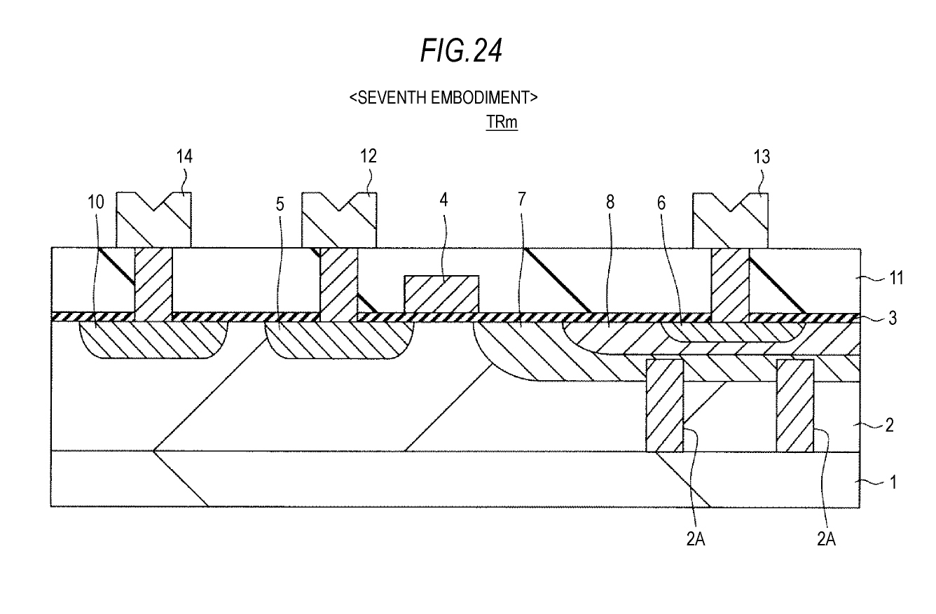

FIG. 24 is a sectional view of a MOS transistor-type protection device TRm related to the seventh embodiment.

As a method of causing avalanche breakdown separately in the resistive breakdown region 8 and the drain region 6, a region in which impurity concentration of the P-well 2 is locally made higher is provided in a part of the P-well 2 in contact with the drain region. This region has a function of easily causing avalanche breakdown, and called a breakdown-facilitated region 2A.

The breakdown-facilitated region 2A may be in contact with or close to the resistive breakdown region 8. The junction withstand voltage in the part of the resistive breakdown region 8 or the drain region 6 in contact with or close to the breakdown-facilitated region 2A is locally reduced. Thereby, junction breakdown becomes easier to occur at the leading end of the end (convex part 8A) of the resistive breakdown region 8 and the region in the resistive breakdown region 8 in contact with or close to the breakdown-facilitated region 2A.

Note that the breakdown-facilitated region 2A may cause either of the first or second avalanche breakdown depending on the impurity concentration and location. Even the location of the first avalanche breakdown may be in the resistive breakdown region 8 or the drain region 6.

In the above described first to seventh embodiments, regarding the resistive breakdown region 8, the metallurgical junction form of the metallurgical junction and the impurity concentration profile of the resistive breakdown region 8 are determined so that the electric neutral region 8i remains in the resistive breakdown region 8 when the breakdown of the drain region 6 or the resistive breakdown region 8 occurs (common requirement).

However, when the breakdown-facilitated region 2A is added, the first breakdown easily occurs. In this case, the first breakdown occurs with assistance of the breakdown-facilitated region 2A, and is not purely determined depending on the metallurgical junction form and the impurity concentration profile of the resistive breakdown region 8. Therefore, the resistive breakdown region 8 in this case may not necessarily fulfill the common requirement. Accordingly, in the case where the breakdown-facilitated region 2A exists, the common requirement may not be a necessary requirement.

Thus, the requirement imposed on the resistive breakdown region 8 in this case that at least one breakdown-facilitated region 2A with opposite conductivity to the resistive breakdown region 8 is provided apart from the well part immediately below the gate electrode at a predetermined distance in contact with or close to the resistive breakdown region 8 is sufficient.

Here, the location and number of the breakdown-facilitated region 2A are not limited. If there are plural regions, it is desirable that the arrangement of the plural breakdown-facilitated regions 2A may be discretized for distribution of the heat generation location.

### 8. Eighth Embodiment

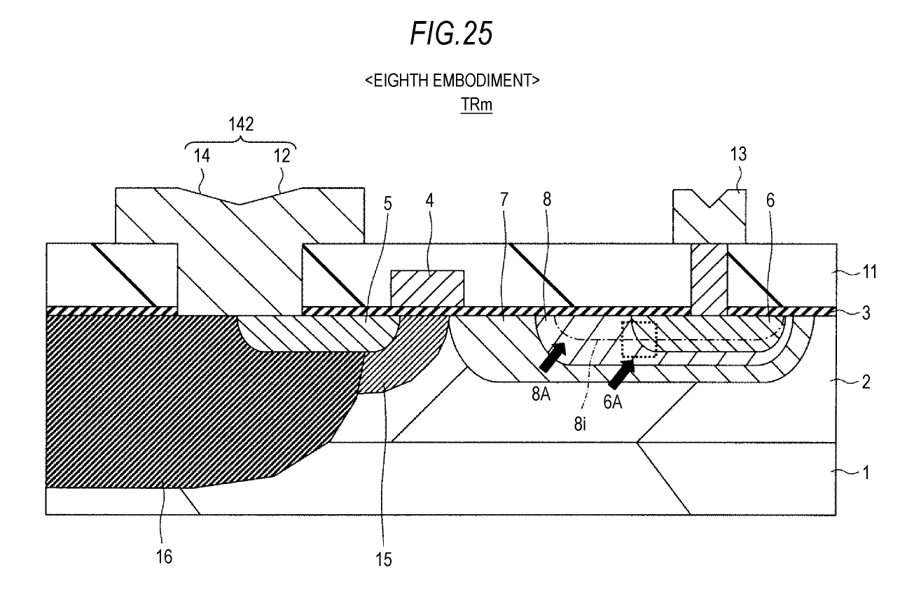

FIG. 25 is a sectional view of a MOS transistor-type protection device TRm related to the eighth embodiment.

The embodiment is an application to a RESURF LDMOS transistor. The structure shown in FIG. 25 differs from the structure FIG. 19A in the following two points.

First, the RESURF LDMOS transistor has a sinker region 16 of high-concentration P-type semiconductor.

Second, the RESURF LDMOS transistor has a channel formation region 15 of P-type semiconductor extending from the source side by diffusion toward below the well electrode 14. In FIG. 25, the source electrode 12 and the well electrode 14 are formed by one electrode (hereinafter, referred to as source and well electrode 142), however, they may be isolatedly provided as is the case of FIG. 19A.

In the structure shown in FIG. 25, when an ESD surge enters the drain electrode 13 and the drain voltage rises, first, the electric field relaxation region 7 is depleted by a depleted layer extending from the P-well 2 or the semiconductor substrate 1 of P⁺ semiconductor. Thereby, the electric field is concentrated on the convex part 6A as the junction part of the drain region 6 having curvature or the convex part 8A as the junction part having curvature at the end of the resistive breakdown region 8 and avalanche breakdown occurs. In this regard, the resistive breakdown region 8 functions as the resistance layer (electric neutral region 8i) having a predetermined resistance value. Accordingly, the same effect as that in the first embodiment that has been summarized in the second embodiment can be obtained in the eighth embodiment. Although not aligned in FIG. 25, the surface edges of the electric field relaxation region 7, the resistive breakdown region 8, and the drain region 6 at the opposite side to the gate may be aligned as those in FIG. 19A. When the edges are aligned, breakdown easily occurs here, and an advantageous structure for distributing heat generation locations can be obtained.

Here, the case where the junction depths of the drain region 6, the resistive breakdown region 8, and the electric field relaxation region 7 are deeper in the opposite order to that in FIG. 2 is shown. In this case, the remaining thickness of the electric neutral region at drain breakdown becomes zero in the electric field relaxation region 7 or thinner than the electric neutral region 8i of the resistive breakdown region 8. Alternatively, the electric neutral region 8i of the resistive breakdown region 8 becomes thinner than the drain region 6 (strictly, its electric neutral region).

Thereby, corners of the electric neutral regions are formed on the convex part 8A as the leading end part of the resistive breakdown region 8 and the convex part 6A of the drain region. On this part, the electric field is concentrated and the breakdown voltage becomes lower, and the same advantage as that of the structure in FIG. 2 can be obtained.

This point is the same advantage as that of FIG. 19A.

As has been explained in the description of FIG. 19A, in this way, the advantage in the embodiments of the invention emerges not depending on the contour shape of the metallurgical junction surface, more intrinsically, depending on the contour shape of the electric neutral region from the drain region to the electric neutral region at drain breakdown.

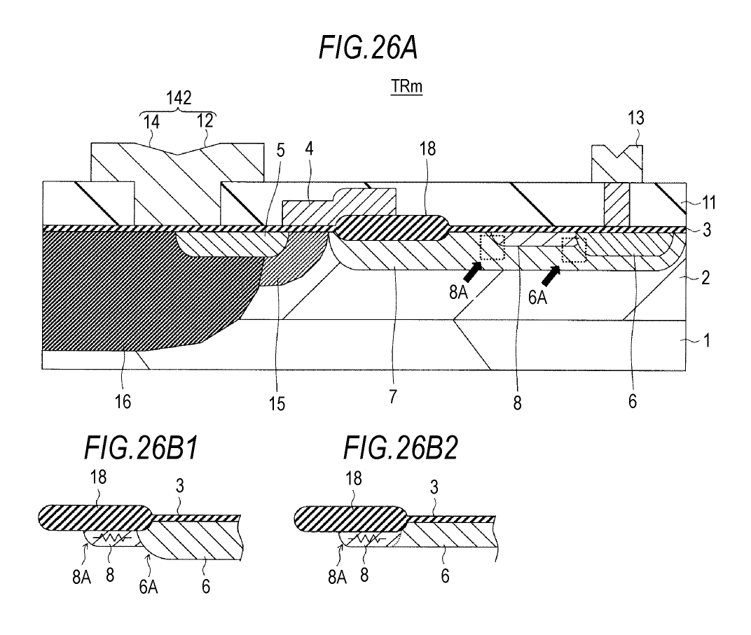

FIG. 26A shows another structure example in the eighth embodiment.

The structure shown in FIG. 26A is formed by introducing a field plate structure into the structure in FIG. 25.

The gate electrode 4 forms the field plate structure by running on one side of a LOCOS insulating film 18.

The electric field relaxation region 7 enters from the immediately below the drain region 6 to under the LOCOS insulating film 18 and spreads close to the channel formation region 15 immediately below the gate.

The resistive breakdown region 8 and the drain region 6 may be formed at the opposite side to the gate of the LOCOS insulating film 18 as shown in FIG. 26A. Alternatively, the gate side of the resistive breakdown region 8 may be extended to immediately below the LOCOS insulating film by designing the impurity distribution to form the convex part 6A. Further, the drain region 6 may be formed by self-alignment with the LOCOS insulating film 18, and the convex part 6A may be provided near the end or immediately below the LOCOS insulating film 18.

FIGS. 26B1 and 26B2 show sectional structures when the end of the drain region 6 reaches to immediately below the LOCOS insulating film 18.

For formation of the convex part 6A as in FIG. 26B1, the junction depth of the resistive breakdown region 8 immediately below the LOCOS insulating film 18 may be smaller than the junction depth of the drain region 6. Alternatively, to the degree that the convex part 6A is not formed as in FIG. 26B2, the junction depths of the resistive breakdown region 8 and the drain region 6 immediately below the LOCOS insulating film 18 may be nearly equal.

In either case, the resistive breakdown region 8 functions as the resistance layer, and generation points of junction breakdown are distributed in a broad region from the convex part 8A to the convex part 6A if there is the convex part 6A, and further, to the bottom surface of the drain region 6.

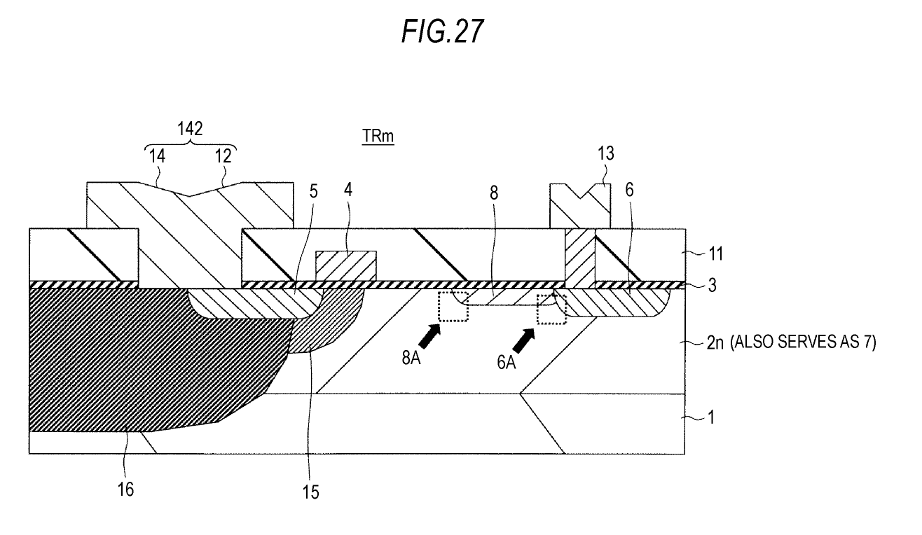

FIG. 27 shows another structure example in the eighth embodiment.

The structure shown in FIG. 27 is a structure formed by replacing the P-well 2 of the structure in FIG. 25 with an N-well 2n. In this structure, it is not necessary to isolatedly provide the electric field relaxation region 7, and the N-well 2n also serves as the electric field relaxation region 7.

In the structure, when an ESD surge is applied, the N-well 2n is depleted by the depleted layer from the semiconductor substrate 1 of P⁺ semiconductor. The advantage after that is the same as that in the structures in FIGS. 2 and 25.

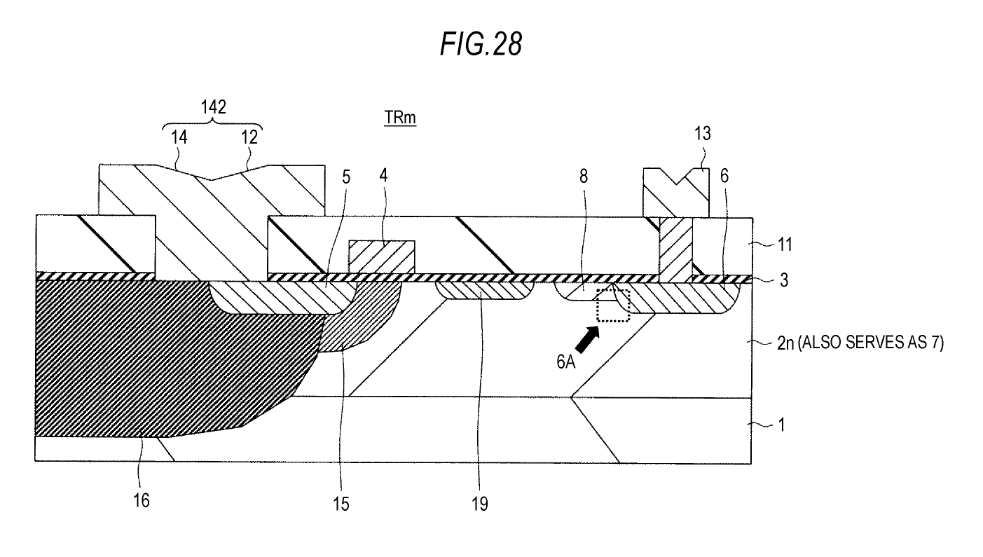

FIG. 28 shows another structure example in the eighth embodiment.

FIG. 28 shows a transistor sectional structure when the structure in FIG. 27 is altered into a double RESURF structure.

This structure differs from that in FIG. 27 in that a P-type region (hereinafter, referred to as a surface side P region 19) is provided on the substrate surface of the electric field relaxation region 7.

The surface side P region 19 has an effect of depleting the electric field relaxation region 7 (the N-well 2n, in this case) by the vertical electric field from above at application of the drain voltage. In this case, the resistive breakdown region 8 may be provided between the drain region 6 and the surface side P region 19 preferably in contact with the drain region 6. Alternatively, the resistive breakdown region 8 may be provided to partially overlap with the surface side P region 19. In this case, the resistive breakdown region 8 may not necessarily form an N-type region from the substrate surface, but the uppermost surface of the substrate may be the P-type region 19 and the N-type region of the resistive breakdown region may be formed underneath.

The above described first to eighth embodiments may be arbitrarily combined.

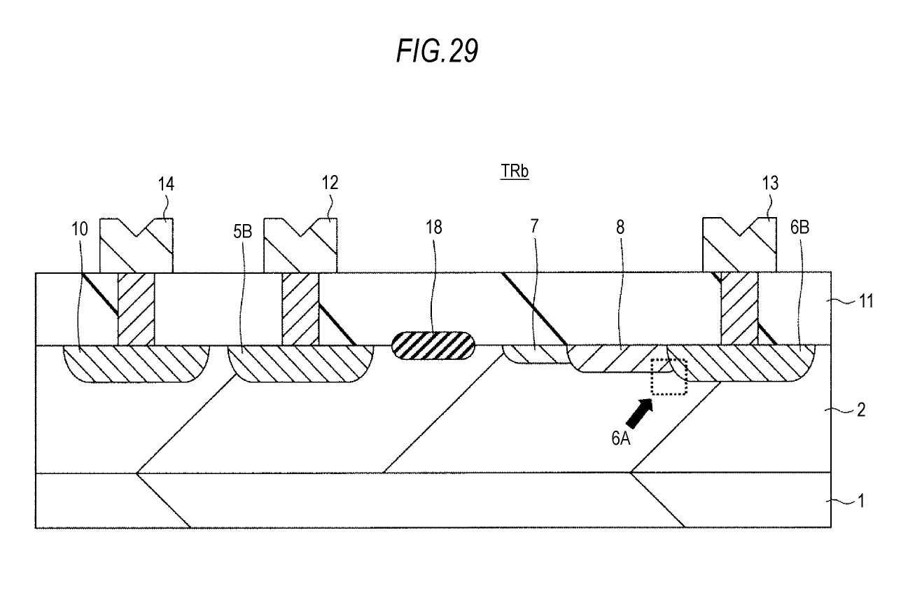

For example, as shown in FIG. 29, the embodiments of the invention can be applied to a field MOSFET.

The working example differs from FIG. 2 in that the gate electrode part of the structure in FIG. 2 is replaced with the LOCOS insulating film 18. With no gate, a bipolar transistor-type protection device TRb is intrinsically the same as that in FIG. 17. The advantage is the same as that in FIGS. 2 and 17.

According to the protection device related to the above described first to eighth embodiments, the junction breakdown occurring due to application of ESD surge is distributed at plural points or broadly generated in a broad region to some degree. Thereby, the concentration of heat generation caused by surge current maybe relaxed and breakage of the protection device due to heat generation concentration at snapback may be avoided. Further, while the high drain voltage is maintained, the electrostatistic breakage withstand voltage comparable to that of a low-voltage protection device can be obtained.

In the first embodiment, the manufacturing method of the protection device has been explained by taking a DEMOS (Drain-Extended MOSFET) having the electric field relaxation region between the gate and the drain for obtainment of high drain withstand voltage as an example.

Further, in the manufacturing method of the protection device related to the first embodiment, two steps (lithography step and ion implantation step) are added to the typical DEMOS. By the addition of the two steps, the resistive breakdown region at higher impurity concentration than that in the electric field relaxation region can be formed between the electric field relaxation region and the drain region.

However, in the manufacturing method, for formation of the protection device, the manufacturing steps include the additional two steps. This increases the cost for manufacturing wafers and inhibits introduction of the products using the protection devices into market. Accordingly, a method of manufacturing the protection device only by the existing manufacturing steps, that is, without additional steps.

Next, embodiments of manufacturing methods with the smaller number of steps and the lower cost at formation of the structure shown in any one of the first to eighth embodiments and their modified examples will be explained. The following embodiments may be applied to the structure of the protection device in any one of the first to eighth embodiments.

A technique of reducing the number of steps will be explained by representatively taking an integrated circuit (IC) having a MOS transistor-type protection device TRm with a basic structure of the fourth embodiment (FIG. 18) as an example. The following embodiments can be analogically applied to the other embodiments than the fourth embodiment of the first to eighth embodiments.

Accordingly, in the description as below, “transistor-type protection device (TRm,b)” will be used as a generic term of the protection device regardless whether the device is of MOS transistor-type or bipolar transistor-type.

### 9. Ninth Embodiment

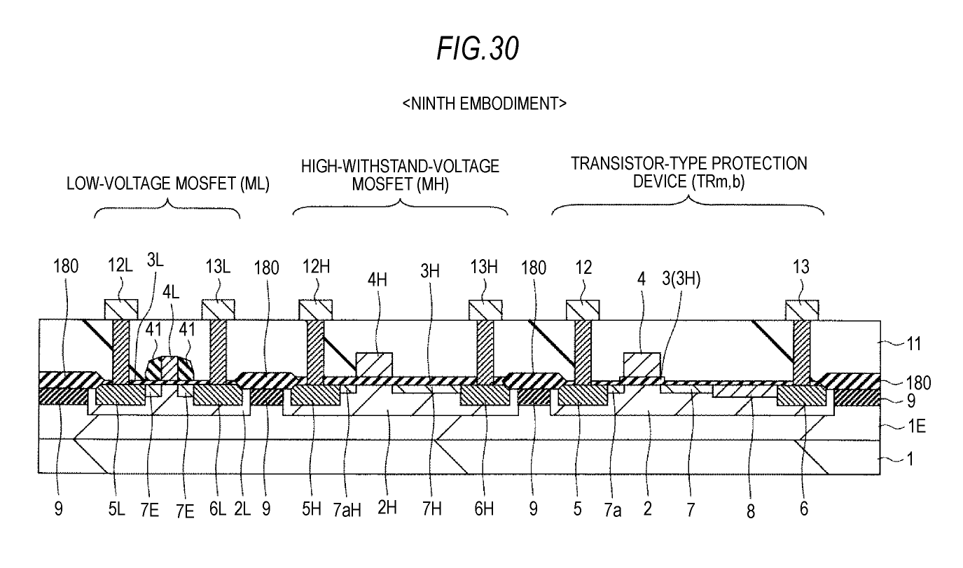

FIG. 30 is a sectional structure diagram of an integrated circuit formed according to a manufacturing method related to the ninth embodiment.

FIG. 30 shows the transistor-type protection device (TRm,b) of the fourth embodiment shown in FIG. 18 with a high-withstand-voltage MOSFET (MH) and a low-voltage MOSFET (ML) formed on the same substrate.

Here, the high-withstand-voltage MOSFET (MH) is a device to be protected from the ESD surge by the transistor-type protection device (TRm,b). That is, the high-withstand-voltage MOSFET (MH) is contained in the internal circuit in FIGS. 1A and 1B. The high-withstand-voltage MOSFET (MH) includes one or both of an N-channel type and a P-channel type. In FIG. 30, only the N-channel MOSFET is shown for avoiding complication of the drawing.

Further, the low-voltage MOSFET (ML) may be contained within the internal circuit, however, here, is a transistor within another circuit block not appearing in FIGS. 1A and 1B.

The low-voltage MOSFET (ML) may be a logic MOSFET forming a control circuit of the high-withstand-voltage MOSFET (MH), for example. Alternatively, the low-voltage MOSFET (ML) may be a logic MOSFET forming a control circuit of an image sensing device formed on the same substrate as that of the high-withstand-voltage MOSFET (MH).

In either case, the low-voltage MOSFET (ML) may be one or both of an N-channel MOSFET and a P-channel MOSFET. In FIG. 30, only the N-channel MOSFET is shown for avoiding complication of the drawing. Note that the low-voltage MOSFET (ML) may contain one or both of a low-voltage N-channel MOSFET and a P-channel MOSFET having different operation voltages formed on the same substrate.

The semiconductor substrate 1 is a silicon (crystal plane orientation 100) substrate with a P-type impurity such as boron (B) injected at high concentration. On the surface of the semiconductor substrate 1, an epitaxial growth layer 1E of low-concentration P-type crystal silicon is formed.

On the surface side of the epitaxial growth layer 1E, wells suitable for the respective devices are formed. Within each well, one of the transistor-type protection device (TRm,b), the high-withstand-voltage MOSFET (MH), and the low-voltage MOSFET (ML) is formed.

Device isolation insulating films 180 for securing electric insulation are formed between the respective devices. In the parts of the epitaxial growth layer 1E in contact with the device isolation insulating films 180, a P-type channel stopper impurity is injected at high concentration and the channel stopper regions 9 are formed.

The low-voltage MOSFET (ML) is formed in a P-type well (P-well 2L) with an impurity injected so that desired threshold voltages or withstand voltages of the respective parts may be obtained. The low-voltage MOSFET (ML) is formed by the following elements:
a gate insulating film 3L for low-voltage MOSFET (e.g., a silicon thermally oxidized film having a thickness of 1 to 10 [nm]);
a gate electrode 4L (e.g., a high-concentration N-type polysilicon electrode);
an extension region 7E of N⁺ semiconductor (a P-type halo region (not shown) may be formed nearby);
a source region 5L of N⁺ semiconductor;
a drain region 6L of N⁺ semiconductor; and
a gate-side-wall insulating film 41 for forming the source region 5L and the drain region 6L by self-alignment relative to the gate electrode 4L.

The high-withstand-voltage MOSFET (MH) is formed in a P-type well (P-well 2H) with an impurity injected so that desired threshold voltages or withstand voltages of the respective parts maybe obtained. The high-withstand-voltage MOSFET (MH) is formed by the following elements:
a gate insulating film 3H for high-withstand-voltage MOSFET (e.g., a silicon thermally oxidized film having a thickness of 10 to 100 [nm]);
agate electrode 4H (e.g., a high-concentration N-type polysilicon electrode);
an electric field relaxation region 7H of N⁻ semiconductor for relaxing concentration of the electric field between the gate and the drain on the gate end and obtaining the high drain withstand voltage;
a source region 5H of N⁺ semiconductor; and
a drain region 6H of N⁺ semiconductor.

The transistor-type protection device (TRm,b) includes the gate insulating film 3, gate electrode 4, source region 5, drain region 6, electric field relaxation region 7, low-concentration region 7a, resistive breakdown region 8, source electrode 12, and drain electrode 13 that have been already explained in the first embodiment.

Here, like in the second to fourth embodiments, the gate electrode 4, the electric field relaxation region 7, and the low-concentration region 7a may not be necessary component elements but arbitrarily be omitted. Further, the transistor-type protection device (TRm,b) may be formed like the MOS transistor-type protection device TRm shown in the fifth to eighth embodiments.

The gate insulating film 3H of the high-withstand-voltage MOSFET (MH) is typically formed thicker than the gate insulating film 3L of the low-voltage MOSFET (ML).

The gate insulating film 3 of the transistor-type protection device (TRm,b) may be formed simultaneously with either the gate insulating film 3H or 3L. Note that, when the gate electrode 4L is provided as in FIG. 30, it is preferable that at least the part immediately below the gate electrode is formed simultaneously with the gate insulating film 3H.

The ninth embodiment is different from the manufacturing method of the first embodiment in that the resistive breakdown region 8 is formed at the same steps of those of the extension region 7E of the low-voltage MOSFET (ML). As far as the transistor-type protection device is concerned, the manufacturing method is the same as that of the first embodiment (FIGS. 4A to 7).

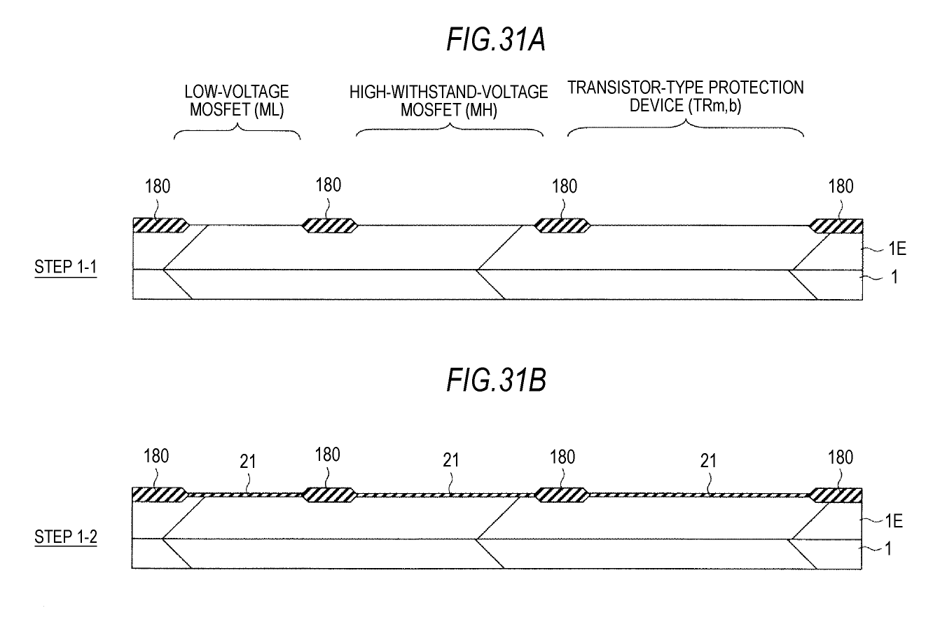

Next, the structure shown in FIG. 30 will be explained with reference to FIGS. 31A to 40B.

Here, the explanation of the same steps as those of the first embodiment will be simplified by appropriately citing terms in FIGS. 4A to 7 and steps 1 to 7. If there are additional steps, for example, new steps to be added between step 3 and step 4 or steps when the step 3 is segmented are expressed by the notation of step 3-1, 3-2, . . . . When the transistor-type protection device in the second to eighth embodiments is integrated, the explanation will be appropriately added by the description as below.

At step 1-1 in FIG. 31A, like at step 1 in FIG. 4A, the P-type epitaxial growth layer 1E is grown on the P-type semiconductor substrate 1. Subsequently, the device isolation insulating films 180 are formed on the surfaces of the respective transistors except active regions. The device isolation insulating films 180 may be formed by a so-called LOCOS process or STI (Shallow Trench Isolation) process.

At step 1-2 in FIG. 31B, sacrifice oxide films 21 are formed in the same manner at step 1 in FIG. 4A. The thickness of the sacrifice oxide films 21 is about 10 to 30 [nm], for example.

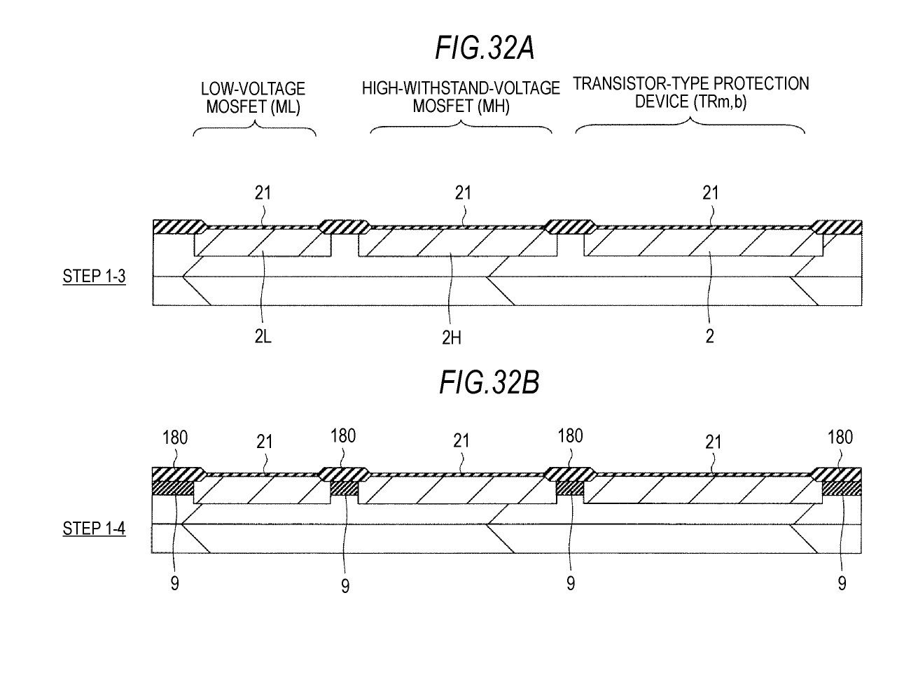

At step 1-3 in FIG. 32A, ion implantation is performed in the same manner at step 1 in FIG. 4A.

Note that, here, a P-type impurity is sequentially ion-implanted through the sacrifice oxide films 21 into the active regions of the respective transistors. The selective ion implantation into the respective regions is performed, for example, by covering the entire substrate surface with a resist film (not shown), then opening the active regions of the target transistors by photolithography, and ion-implanting the resist as a mask. For example, boron (B) may be used as the impurity to be implanted. The implantation condition is determined so that desired threshold voltages maybe obtained in the respective transistors. Here, ion implantation maybe performed simultaneously into the P-well 2H and the P-well 2.

At step 1-4 in FIG. 32B, the impurity to be the channel stoppers are ion-implanted through the sacrifice oxide films 21 into the device isolation regions, and the channel stopper regions 9 are formed.

The P-type channel stopper regions 9 are formed in a P-type regions around the N-channel MOSFET by implanting a P-type impurity such as boron (B) and N-type channel stopper regions (not shown) are formed in the N-type regions around the P-channel MOSFET by implanting an N-type impurity such as phosphorus (P). The concentration of the implanted impurity is determined from the thickness of the device isolation insulating films 180 and the power supply voltage so that no inversion layer may be formed immediately below the device isolation insulating films 180.

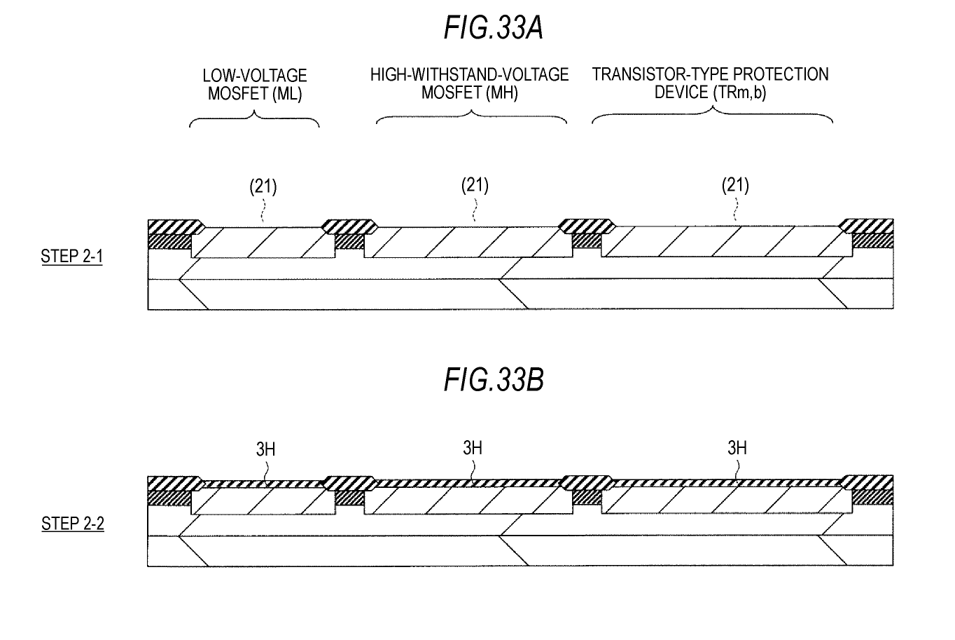

At step 2-1 in FIG. 33A, the sacrifice oxide films 21 are removed in the same manner as at step 2 in FIG. 4B.

At step 2-2 in FIG. 33B, the semiconductor substrate 1 is thermally oxidized and the gate insulating film 3H for the high-withstand-voltage MOSFET is formed. In this regard, the impurity injected into the semiconductor substrate 1 at step 1-4 or before is activated. The thermal oxidation may be performed by heating the substrate in an atmosphere containing oxygen to 900 to 1100 [° C.], for example. The thickness of the oxide film may be determined according to the gate drive voltage of the high-withstand-voltage MOSFET, and may be set to 10 to 100 [nm], for example.

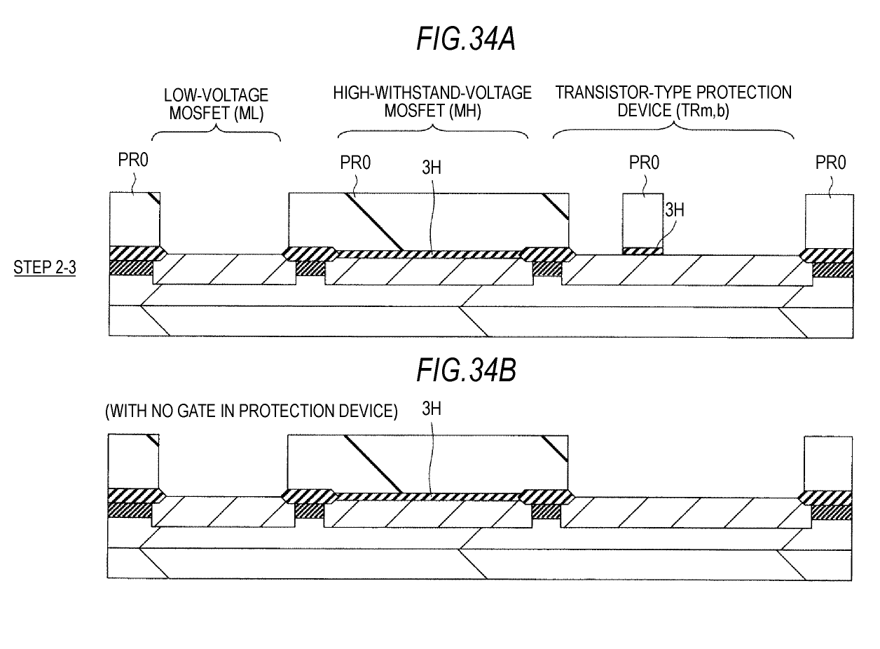

At step 2-3 in FIG. 34A, a resist PRO is formed on the surface of the semiconductor substrate, and then, the active regions of the low-voltage MOSFET (ML) and the transistor-type protection device (TRm,b) are opened by photolithography.

If the gate electrode is provided on the transistor-type protection device (TRm,b), as in FIG. 34A, the resist PRO is left in and near the gate region of the transistor-type protection device (TRm,b). If not, as in FIG. 34B, the resist PRO is not left in and near the gate region of the transistor-type protection device (TRm,b).

Subsequently, the gate insulating films 3H in the resist opening parts are removed.

Then, the resist PRO is removed. This removal may be performed by reactive ion etching with a reactive gas containing silane (CF₄), immersion in a solution containing hydrofluoric acid, or a combination of them.

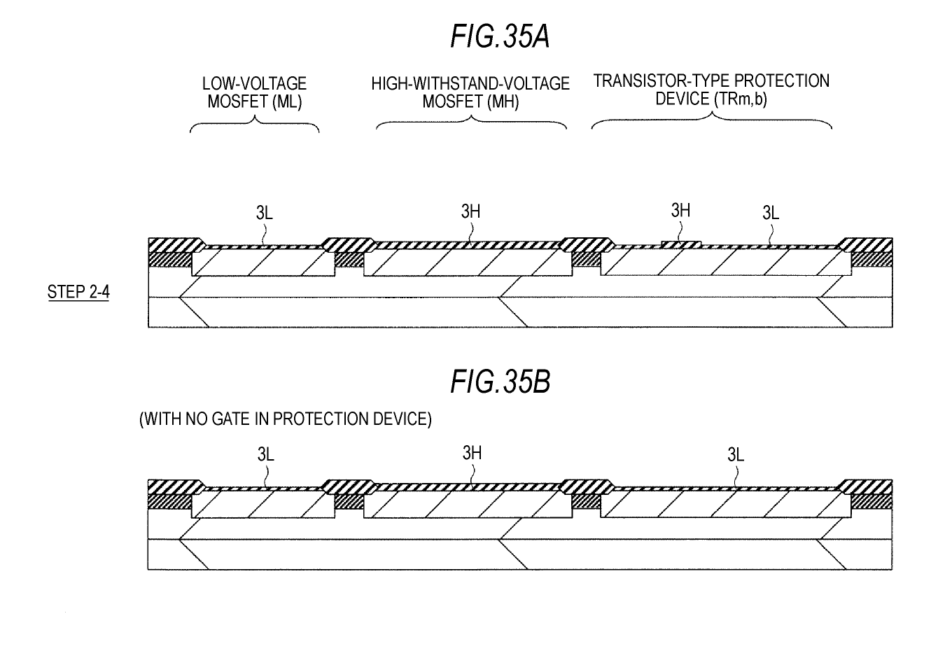

At step 2-4 in FIG. 35A, the surface of the semiconductor substrate is thermally oxidized and the gate insulating film 3L for the low-voltage MOSFET (ML) is formed. The thickness of the thermally oxidized film may be determined according to required characteristics of the low-voltage MOSFET (ML), and set to 1 to 10 [nm].

In the formation region of the transistor-type protection device (TRm,b), the gate insulating film 3H having a slightly increased thickness is formed in the gate formation part, and the gate insulating film 3L is formed on the surrounding semiconductor active region surface.

FIG. 35B shows a section with no gate formed, and the gate insulating film 3L is formed on the entire semiconductor active region surface of the formation region of the transistor-type protection device (TRm,b).

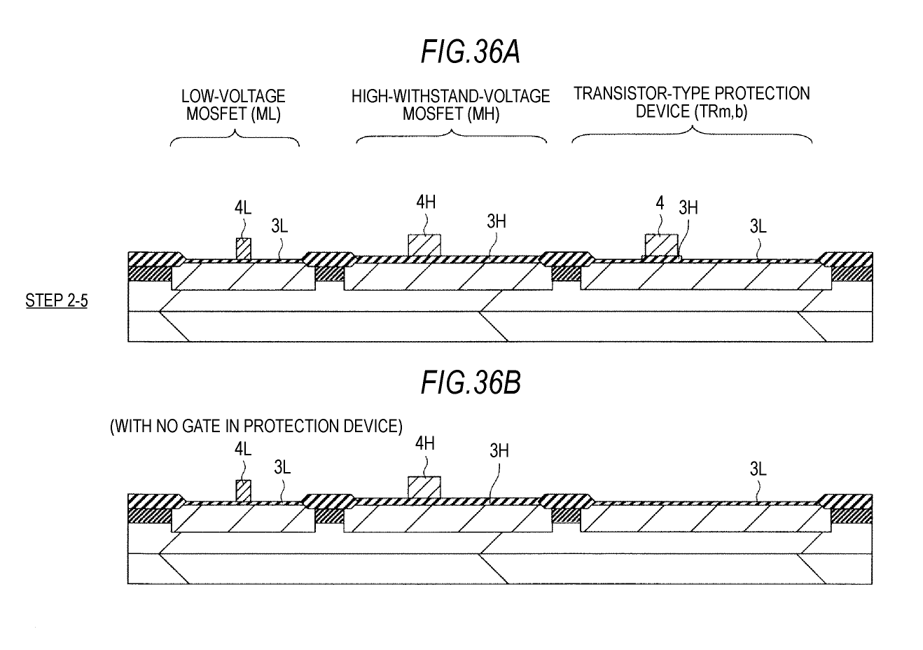

At step 2-5 in FIG. 36A, the gate electrodes of the respective transistors are formed in the following procedure.

For formation of the gate electrodes, first, a polysilicon layer is deposited in about 100 to 200 [nm] by CVD on the surface of the semiconductor substrate, and then, covered by a resist film (not shown). Phosphorus ions are injected into the polysilicon layer during or after deposition and the conductivity of the layer is raised.

Subsequently, the resist is left only on the gate regions of the respective transistors by lithography, and then, reactive ion etching is performed using a reactive gas containing silane (CF₄) and the polysilicon layer in the regions not covered by the resist is removed.

Then, the resist is removed and the gate electrodes 4L, 4H, 4 made of polysilicon are obtained as in FIGS. 36A and 36B.

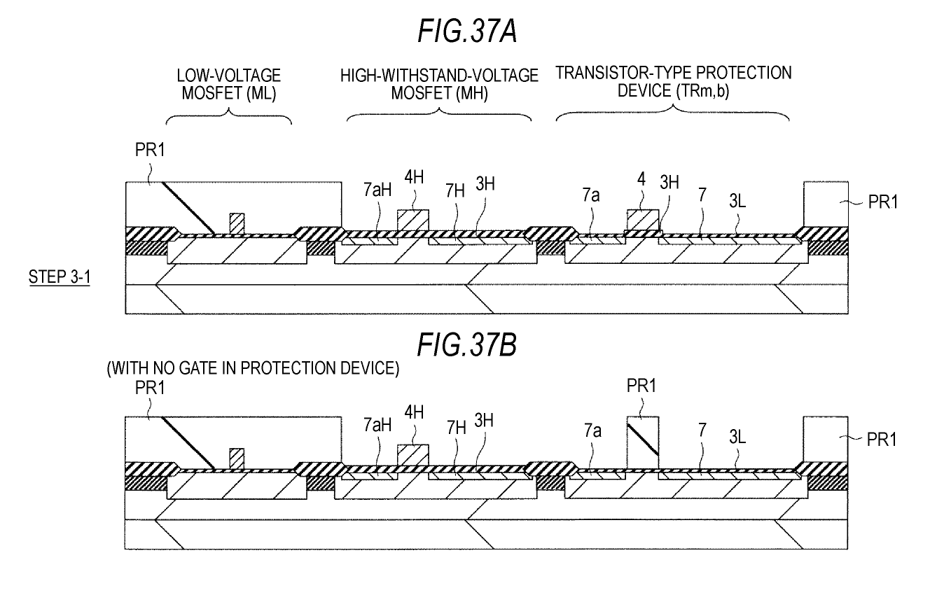

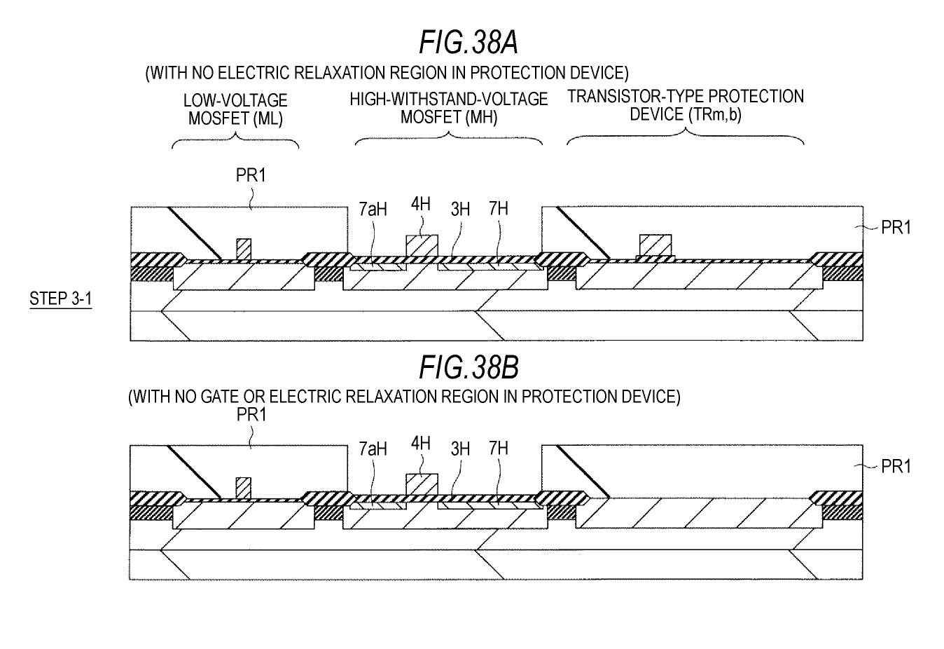

At step 3-1 in FIGS. 37A to 38B, the regions other than the active regions of the high-withstand-voltage MOSFET (MH) and the transistor-type protection device (TRm,b) are covered by resists PR1.

When the gate electrode is not provided in the protection device, as shown in FIG. 37B, a dummy gate is provided by the resist PR1 within the active region of the protection device.

When the electric field relaxation region is not provided in the protection device, as shown in FIG. 38A, the regions other than the active region of the high-withstand-voltage MOSFET (MH) is covered by the resists PR1.

Subsequently, phosphorus (P) is ion-implanted into the semiconductor substrate 1 using the resists PR1 as a mask, and the impurity in the electric field relaxation region is injected. The amount of doze and implantation energy of the phosphorus (P) are selected so that desired on-resistance and drain withstand voltage may be obtained in the high-withstand-voltage MOSFET (MH).

Thereby, as shown in FIGS. 37A to 38B, the electric field relaxation region 7H and a low-concentration region 7aH are formed on the high-withstand-voltage MOSFET (MH). Further, in the case of FIGS. 37A and 37B, the electric field relaxation region 7 and the low-concentration region 7a are further formed on the transistor-type protection device (TRm,b).

Then, the resists PR1 are removed.

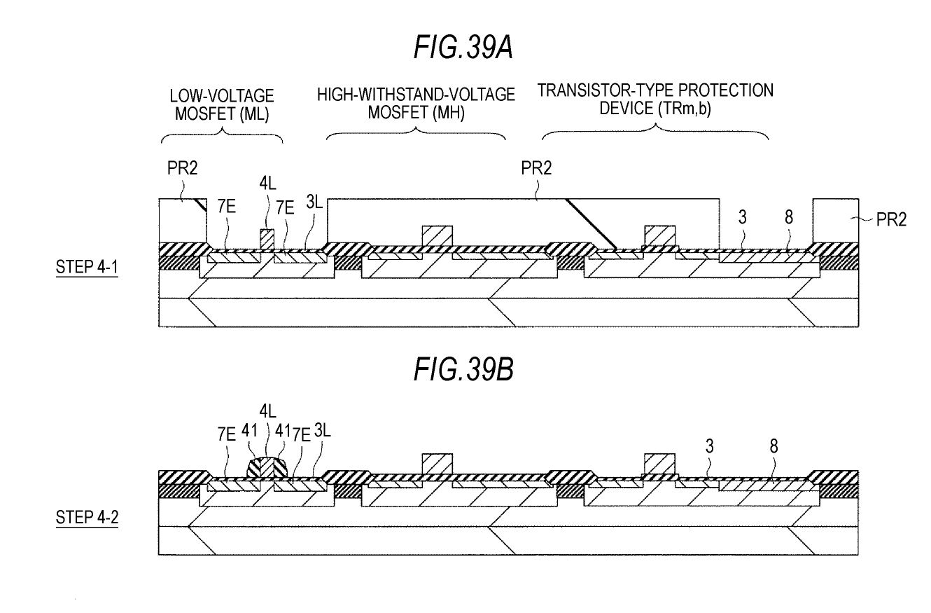

FIG. 39A shows a characteristic step of the embodiment.

At step 4-1 in FIG. 39A, the regions other than the formation region of the low-voltage MOSFET (ML) and the resistive breakdown region of the transistor-type protection device (TRm,b) are covered by resists PR2. Phosphorus (P) is ion-implanted into the semiconductor substrate 1 using the resists PR2 as a mask, and impurities of the extension regions 7E of the low-voltage MOSFET (ML) and the resistive breakdown region 8 of the transistor-type protection device (TRm,b) are simultaneously injected. In this regard, subsequent to the extension impurity, boron fluoride (BF₂) is ion-implanted and a halo region may be formed near the extension regions 7E.

The amounts of dose and implantation energy of the phosphorus (P) and boron fluoride (BF₂) are set so that the requirements for the low-voltage MOSFET (ML) and the transistor-type protection device (TRm,b) may be simultaneously fulfilled.

The requirement for the low-voltage MOSFET (ML) is to suppress the short channel effect.

The first requirement of the transistor-type protection device (TRm,b) is that the pinch-off voltage of the resistive breakdown region 8 is higher than the drain withstand voltage of the high-withstand-voltage MOSFET (MH). Further, the second requirement to be fulfilled at the same time is that a sheet resistance that provides good allocation of two avalanche breakdown currents when an ESD surge enters and avalanche breakdown occurs in the drain junction may be obtained. Here, the “two avalanche breakdown currents” refer to an avalanche breakdown current generated at the end facing the gate of the resistive breakdown region 8 and an avalanche breakdown current generated in the depleted layer near the drain region.

After the resist PR2 is removed, at step 4-2 in FIG. 39B, the gate-side-wall insulating film 41 is formed around the gate electrode 4L of the low-voltage MOSFET (ML). First, as a film to be the gate-side-wall insulating film 41, an SiO₂ film and an amorphous Si (α-Si) film using TEOS as a raw material are sequentially deposited on the surface of the semiconductor substrate. The deposited α-Si film is etched back by anisotropic reactive ion etching with a reactive gas containing silane (CF₄). Thereby, the gate-side-wall insulating film 41 is formed.

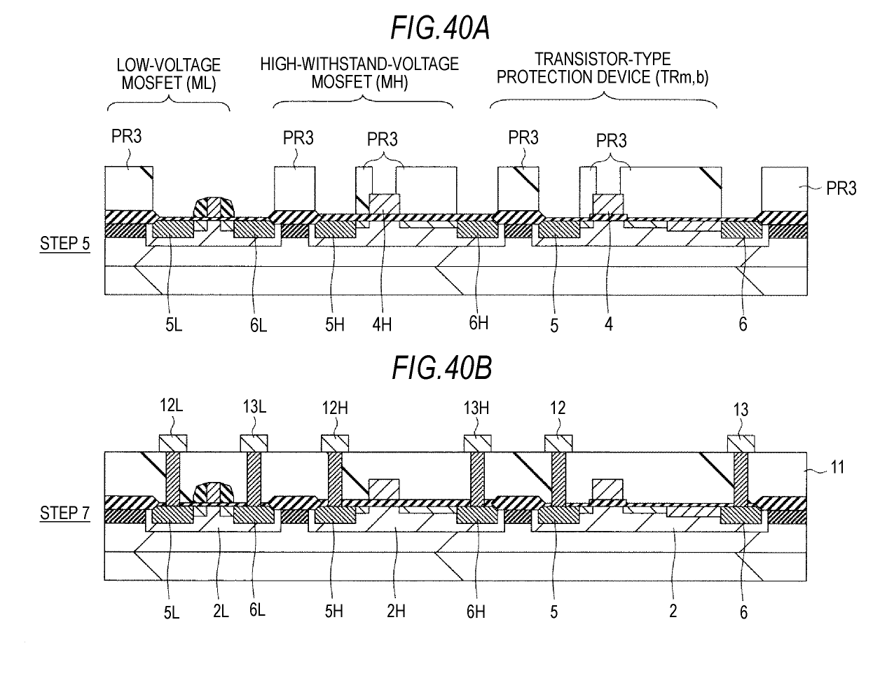

At step 5 in FIG. 40A, the regions other than the formation regions of the sources and the drains of the respective MOSFETs are covered by resists PR3. Then, an N-type impurity is implanted and the impurities of the source and drain regions are injected.

The kinds of ions implanted may be arsenic (As), phosphorus (P), or both of them. The implantation energy and the amounts of doze of the respective ions are selected according to the sheet resistance of the source and drain regions and the contact resistance between the connection hole wiring, which will be formed later, and the source and drain regions to achieve a good balance of the roll-off between the drain withstand voltage and the threshold voltage. Here, the drain withstand voltage to be balanced is the drain withstand voltage of the high-withstand-voltage MOSFET (MH). Further, the threshold voltage to be balanced is the threshold voltage of the low-voltage MOSFET (ML).

After the resists PR3 are removed, the semiconductor substrate is heat-treated and the impurities implanted into the substrate are activated. The heat treatment may be performed by heating the substrate in an anneal furnace at around 1000 [° C.] in several seconds. Alternatively, annealing may be performed in an extremely short time using RTA.

The formation of the well contact region shown at step 6 in FIG. 6B is performed in the respective P-wells 2, 2L, and 2H.

Then, at step 7 in FIG. 40B, the thick interlayer insulating film 11 is deposited on the surface of the semiconductor substrate.

In the interlayer insulating film 11, connection holes are formed on the gate electrodes and the source and drain regions of the respective MOSFETs, and the connection holes are embedded with a metal. In this regard, in order to reduce the connection resistance between the source and drain regions and the embedded metal of the connection holes, a silicide layer may be formed by heat treatment after Co and Ni are evaporated on the surfaces of the source and drain regions in advance.

A metal wiring layer is formed on the interlayer insulating film 11 and isolated into the source electrodes 12, 12L, 12H and the drain electrodes 13, 13L, 13H by optical lithography and etching.

In the above described manufacturing method, the resistive breakdown region 8 is simultaneously formed with the extension regions 7E of the low-voltage MOSFET. Accordingly, the transistor-type ESD protection device can be manufactured at low cost without addition of the steps only for the resistive breakdown region.

### 10. Tenth Embodiment

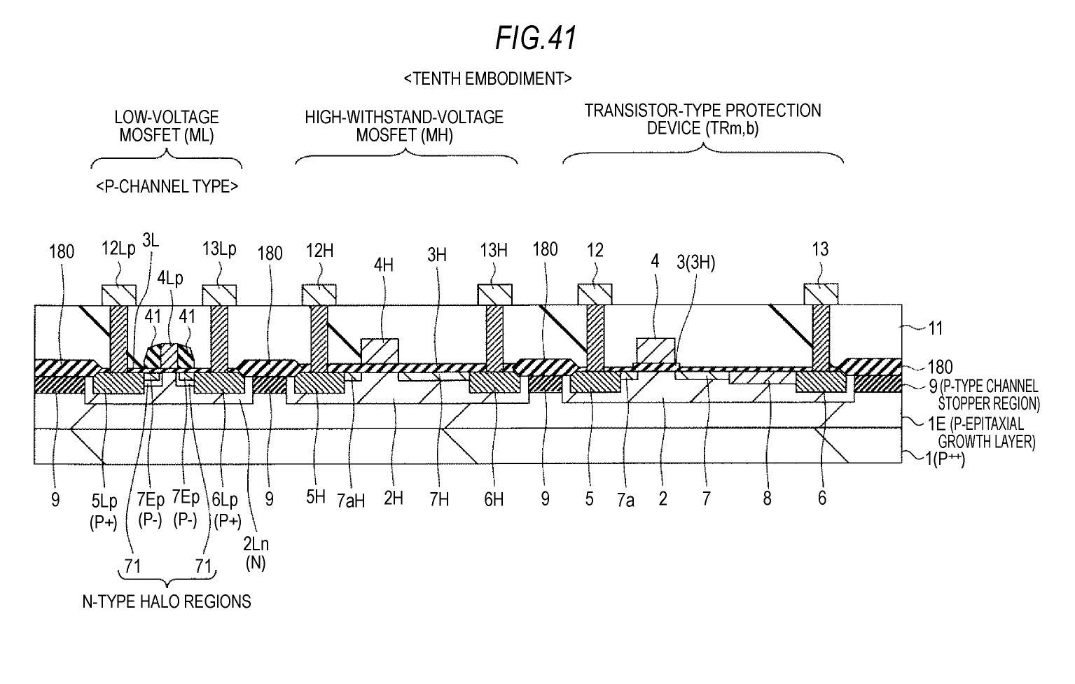

FIG. 41 is a sectional structure diagram of an integrated circuit formed according to a manufacturing method related to the tenth embodiment.

FIG. 41 shows a part of the P-channel low-voltage MOSFET (ML) not appearing in FIG. 30 with the high-withstand-voltage MOSFET (MH) and the transistor-type protection device (TRm,b) formed on the same substrate.

Here, the low-voltage MOSFET (ML) is a P-channel MOSFET having N-type halo regions 71. The halo regions 71 are formed at the substrate depth side of P-type extension regions 7Ep. The halo region 71 is formed slightly larger than the P-type extension region 7Ep at the substrate depth side so that the metallurgical junction with the N-type well (N-well 2Ln) may not be formed in the extension region 7Ep. Note that the shape of the halo region 71 is not limited to that.

The manufacturing method of the embodiment forms the resistive breakdown region 8 simultaneously not with the N-type extension regions 7E but with the N-type halo regions 71 at step 4-1 of forming the resistive breakdown region 8 (FIG. 39A). The embodiment differs from the ninth embodiment in that.

In the ninth embodiment, the formation step of a P-type transistor has already existed though not specifically explained for specialized explanation of the sectional structure of the N-type transistor. Accordingly, the formation of the resistive breakdown region 8 simultaneously with the N-type halo regions 71 may not need any additional manufacturing steps.

In FIG. 41, the gate electrode 4Lp, the source region 5Lp, the drain region 6Lp, the source region 12Lp, the drain region 13Lp with “p” show dedicated use for the P-channel transistor.

### 11. Eleventh Embodiment

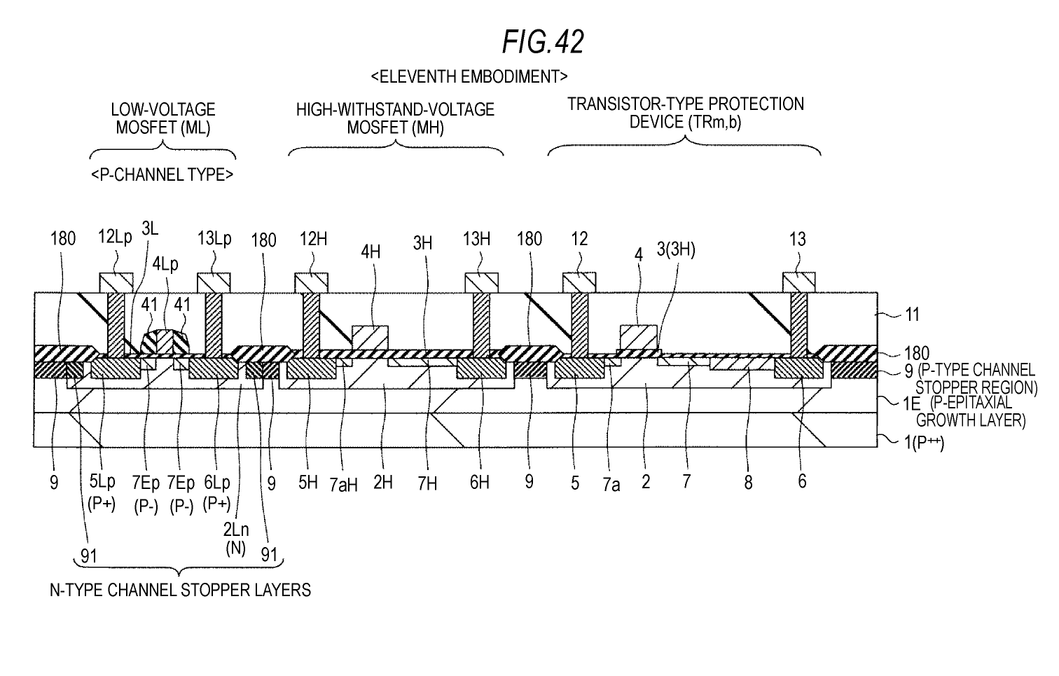

FIG. 42 is a sectional structure diagram of an integrated circuit formed according to a manufacturing method related to the eleventh embodiment.

In FIG. 42, the same signs are assigned to the same components of those in FIG. 41.

The difference between the structure shown in FIG. 42 and the structure in FIG. 41 is that N-type channel stopper regions 91 are provided in the lower parts of the device isolation insulating films 180 of the N-well 2Ln. The N-type channel stopper regions 91 just do not appear in FIGS. 30 and 42, and the lower parts of the device isolation insulating films 180 of the N-well 2Ln are typically of N-type.

The manufacturing method of the embodiment forms the resistive breakdown region 8 simultaneously with the N-type channel stopper regions 91. This differs from the manufacturing methods related to FIGS. 30 and 41.

The formation step of the N-type channel stopper regions 91 is not described in the manufacturing steps of the structure in FIG. 30 (FIGS. 31A to 40B). For example, the resistive breakdown region 8 is simultaneously formed at the existing formation step of the N-type channel stopper regions 91 performed subsequent to the ion implantation of the P-well at step 1-3 (FIG. 32A). In this case, the opening part corresponding to the resistive breakdown region 8 is not formed in the resist PR2 at step 4-1 (FIG. 39A).

### 12. Twelfth Embodiment

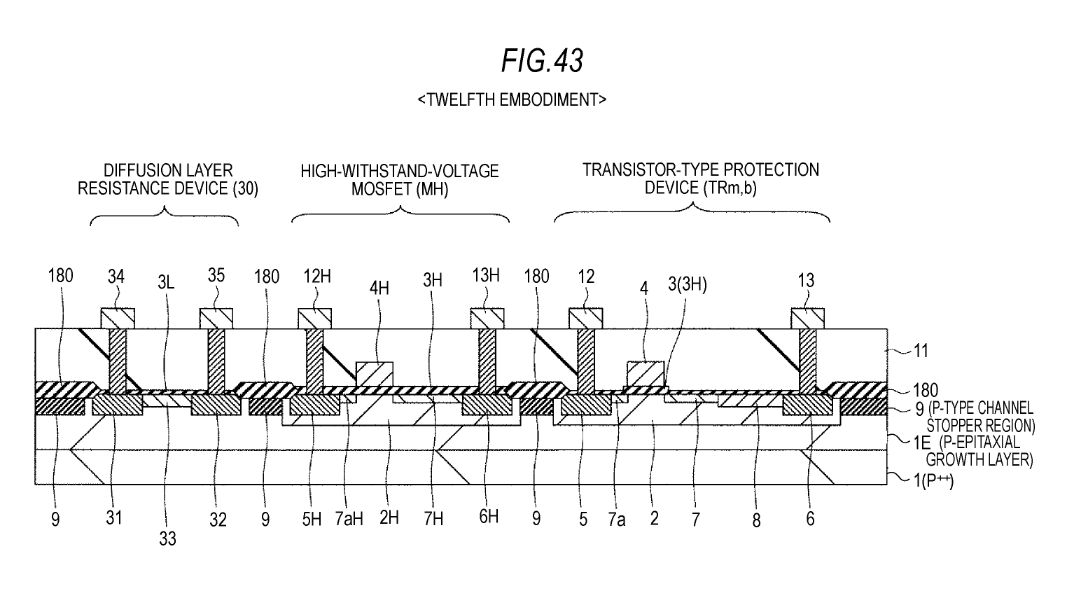

FIG. 43 is a sectional structure diagram of an integrated circuit formed according to a manufacturing method related to the twelfth embodiment.

FIG. 43 shows an N-type diffusion layer resistance device (30) that has not appeared in FIG. 30 with the high-withstand-voltage MOSFET (MH) and the transistor-type protection device (TRm,b) formed on the same substrate.

In the N-type diffusion layer resistance device (30), N-type high-concentration resistance contact regions 31 and 32 are formed isolatedly from each other in the epitaxial growth layer 1E. An N-type resistance region 33 having a predetermined sheet resistance is formed within the epitaxial growth layer 1E to connect between the resistance contact regions 31 and 32.

The resistance contact region 31 is connected to wiring 34 via a plug within the interlayer insulating film 11. Similarly, the resistance contact region 32 is connected to wiring 35 via a plug within the interlayer insulating film 11.

The manufacturing method of the embodiment forms the resistive breakdown region 8 simultaneously not with the N-type extension region 7E but with the N-type resistance region 33 at step 4-1 (FIG. 39A) of forming the resistive breakdown region 8. The embodiment differs from the ninth embodiment in that.

In the ninth embodiment, the formation step of N-type diffusion layer resistance device (30) has already existed though not specifically explained for specialized explanation of the sectional structure of the N-type transistor. Accordingly, the formation of the resistive breakdown region 8 simultaneously with the N-type resistance region 33 may not need any additional manufacturing steps.

### 13. Thirteenth Embodiment

As has been already described, the ninth embodiment as shown in FIG. 30 may arbitrarily combined with the other first to eighth embodiments.

The thirteenth embodiment relates to a combination of the seventh embodiment and the ninth embodiment as it were.

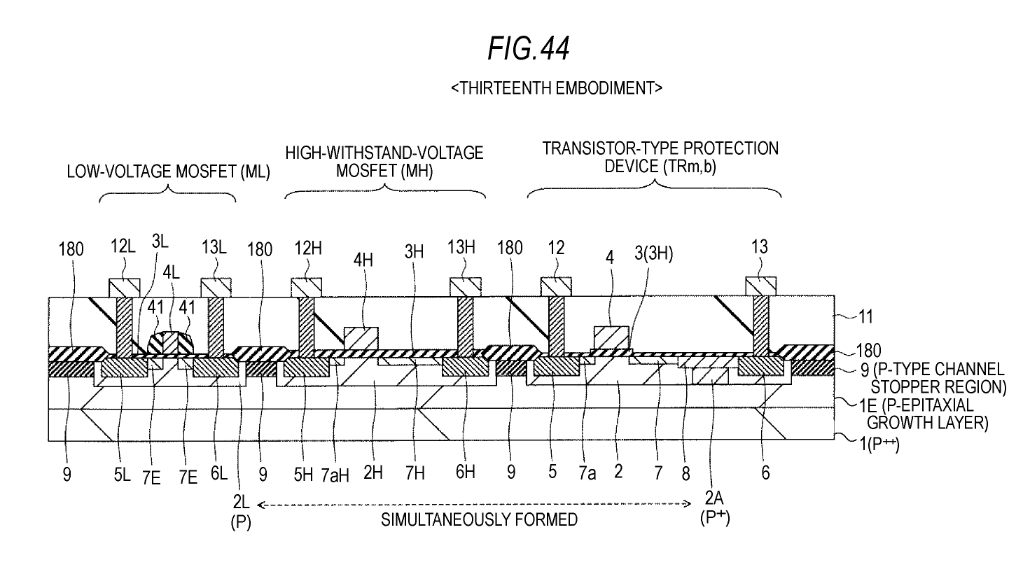

FIG. 44 is a sectional structure diagram of an integrated circuit formed according to a manufacturing method related to the thirteenth embodiment.

In the sectional structure shown in FIG. 44, the breakdown-facilitated region 2A in contact with or close to the resistive breakdown region 8 is formed in the transistor-type protection device (TRm,b) like in the structure of the seventh embodiment shown in FIG. 24.

Here, the breakdown-facilitated region 2A is simultaneously formed with the P-well 2L in the low-voltage MOSFET (ML). Depending on the concentration difference between the P-well 2 and the P-well 2L, whether the concentration of the part in which the breakdown-facilitated region 2A is formed is lower or higher than the surrounding P-well 2 is determined. If the concentration is made higher by the breakdown-facilitated region 2A, junction breakdown occurs more easily in the part of the breakdown-facilitated region 2A than in the other parts of the P-well 2 in contact with the resistive breakdown region 8. On the other hand, if the concentration is made lower by the breakdown-facilitated region 2A, junction breakdown occurs more easily in the other parts of the breakdown-facilitated region 2A than in the part of the the P-well 2 in contact with the resistive breakdown region 8.

Thus, the breakdown-facilitated region 2A has an advantage of limiting the points at which junction breakdown becomes more easily to occur.

Further, by the existence of the breakdown-facilitated region 2A, the P-type impurity concentration near the electric field relaxation region is adjusted, and the sheet resistance at drain junction breakdown can be made closer to a desired value.

### 14. Fourteenth Embodiment

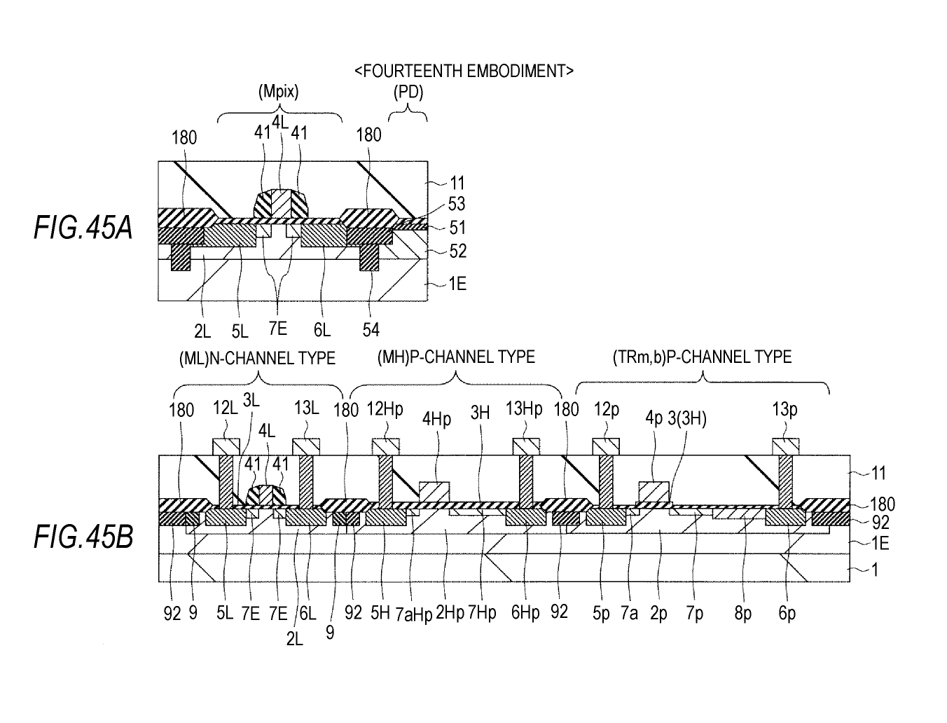

FIGS. 45A and 45B are sectional structure diagrams of an integrated circuit (e.g., a chip of a solid-state image sensing device) formed according to a manufacturing method related to the fourteenth embodiment. FIG. 45B shows the high-withstand-voltage MOSFET (MH), the low-voltage MOSFET (ML), and the transistor-type protection device (TRm,b) formed on the same substrate. Further, FIG. 45A shows a pixel MOSFET (Mpix) and a photosensor (PD) of a CMOS image sensor formed on the same substrate together with the respective devices in FIG. 45B.

The pixel MOSFET (Mpix) in FIG. 45A has the same configuration as that of the low-voltage MOSFET (ML) in FIG. 45B, and fabricated in the same procedure as that of the low-voltage MOSFET (ML). Slight difference of concentration or the like may be acceptable, and the same signs as those of the respective parts of the low-voltage MOSFET (ML) are assigned to the respective parts forming the pixel MOSFET (Mpix) in FIG. 45A for indicating that they are formed at the same time.

The photosensor (PD) is formed by a low-concentration N-type region (N⁻-region) 52 as a photoelectric conversion region and an N-type region (N-region) 51 for avoiding the generation of noise due to the interface state of an interface between the substrate and the oxide film.

Further, the device isolation within the pixel is formed by the thick device isolation insulating films 180 projecting upward from the substrate surface and P-type diffusion isolation regions 53, 54 for securing insulation between the devices within the substrate.

For the fabrication of these pixel MOSFET (Mpix) and photosensor (PD), the known manufacturing method maybe used.

In the embodiment, the transistor-type protection device (TRm,b) is formed by a P-channel GGMOSFET. Further, the P-type resistive breakdown region 8p of the GGMOSFET is formed at one step of the formation step of the P-type diffusion isolation region 53 (upper part), the P-type diffusion isolation region 54 (lower part), and the P⁻-region 36 of the photosensor (PD). Alternatively, these steps maybe arbitrarily combined to form the resistive breakdown region 8p.

The fabrication steps of the pixel MOSFET (Mpix) and the photosensor (PD) are steps existing before application of the embodiment of the invention, the number of steps is not increased by the application of the embodiment of the invention.

The above described first to fourteenth embodiments can be freely combined for implementation as long as they have an exclusive relationship, that is, except the case it is clear that application of one embodiment and the other embodiment may be impossible at the same time.

Further, in the first to fourteenth embodiments and the embodiments in combination thereof, various modifications described as bellow can be made. The following modified examples may be arbitrarily combined.

### Modified Example 1

In the first to fourteenth embodiments and the embodiments in combination of them, an embedded layer can be applied.

For example, the structure in FIG. 2 is taken as an example.

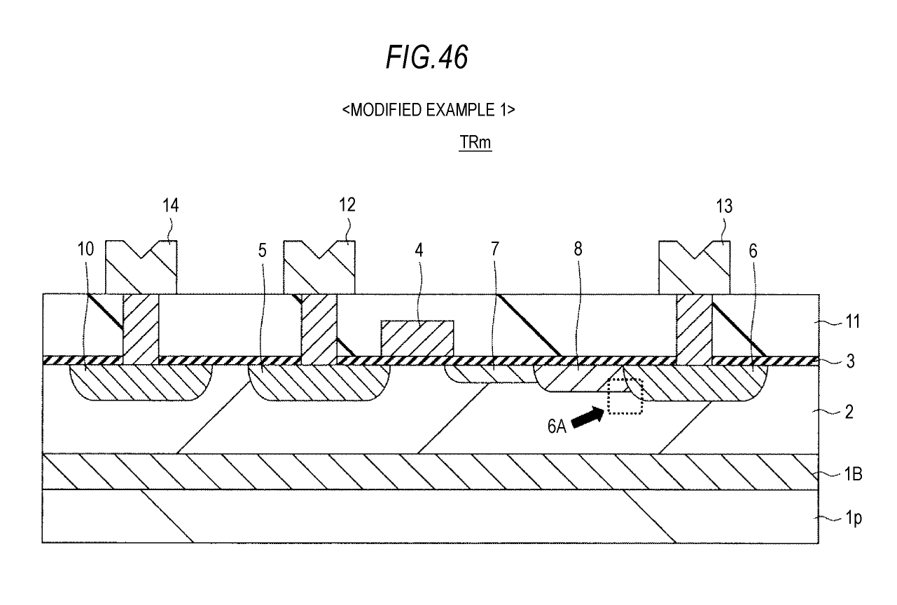

FIG. 46 is a sectional structure diagram showing a modified example when a P-type embedded layer is added to the structure in FIG. 2.

As shown in FIG. 46, in modified example 1, the substrate of the structure in FIG. 2 is replaced with a P⁻-type low-concentration semiconductor substrate 1P, and a P-type embedded layer 1B is further added thereto. According to the configuration, the same effect as that of the first embodiment can be obtained. Further, with the structure in which the P-type embedded layer is replaced with an embedded insulating film, the same effect as that of the first embodiment can be obtained.

### Modified Example 2

In the first to fourteenth embodiments, the impurity concentration of the resistive breakdown regions 8, 8p is depicted to be uniform over the entire length, however, it may not necessarily be uniform but the concentration and junction depth can be partially modulated.

Further, a silicide may be formed at the interface between the drain electrode 13 and the drain region 6 for reducing the contact resistance. Note that, in this case, it is desirable that the silicide layer is formed at 0.1 [μm] or more inside from the perimeter of the drain region.

### Other Modified Examples

In the above described first to fourteenth embodiments and combinations of the embodiments, and modified example 1, the same effect can be obtained even with opposite conductivity type transistors and protection devices fabricated by replacing the conductivity type of the impurities in the respective parts. The opposite conductivity type transistors and protection devices can be fabricated in the same procedure by reversing the conductivity type of the impurities injected at the respective steps in the above described explanation of the manufacturing methods.

The operation voltage (power supply voltage) of the low-voltage MOSFET (ML) may be any of 1.2 [V], 1.8 [V], 3.3 [V], 5 [V], or the like, and the high-withstand-voltage MOSFET (MH) have a higher withstand voltage than the operation voltage of the constant voltage.

The technical idea of the embodiments of the invention can be applied not only to the planar MOSFET but also to a longitudinal MOSFET structure of LDMOS, DMOS, VMOS, UMOS, or the like.

The technical idea of the embodiments of the invention is not limited to the high-concentration P-type substrate having the low-concentration P-type epitaxial layer as the substrate structure, but can be applied to a high-resistance P-type substrate, N-type substrate, SOI substrate, or the like.

The technical idea of the embodiments of the invention is not limited to the device material of Si. In place of Si, other semiconductor materials such as SiGe, SiC, Ge, group-IV semiconductors such as diamond, group III-V semiconductors represented by GaAs and InP, group II-VI semiconductors represented by ZnSe and ZnS may be used.

The technical idea of the embodiments of the invention is not limited to the semiconductor integrated circuit. The technical idea may be applied to a discrete semiconductor device. The semiconductor integrated circuit may be arbitrarily used for a logic IC, memory IC, imaging device, or the like.

The present application contains subject matter related to that disclosed in Japanese Priority Patent Application JP 2008-255556 filed in the Japan Patent Office on Sep. 30, 2008, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A transistor-type protection device comprising:
a semiconductor substrate;
a well including a first-conductivity-type semiconductor formed in the semiconductor substrate;
a source region including a second-conductivity-type semiconductor formed in the well;
a gate electrode formed above the well via a gate insulating film at one side of the source region;
a drain region including the second-conductivity-type semiconductor formed within the well apart at one side of the gate electrode; and
a resistive breakdown region including a second-conductivity-type semiconductor region in contact with the drain region at a predetermined distance apart from the well part immediately below the gate electrode,
wherein a metallurgical junction form and a impurity concentration profile of the resistive breakdown region are determined so that a region not depleted at application of a drain bias when junction breakdown occurs in the drain region or the resistive breakdown region may remain in the resistive breakdown region.

2. The transistor-type protection device according to claim 1, wherein the metallurgical junction form and the impurity concentration profile of the resistive breakdown region are determined so that junction breakdown occurs in the resistive breakdown region under a condition that the region not depleted remains in the resistive breakdown region before or after junction breakdown occurs in the drain region at the application of a drain bias.

3. The transistor-type protection device according to claim 1, wherein a metallurgical junction depth of the drain region is larger than a metallurgical junction depth of the resistive breakdown region.

4. The transistor-type protection device according to claim 1, wherein, while a metallurgical junction depth of the drain region is smaller than a metallurgical junction depth of the resistive breakdown region, the metallurgical junction form and the impurity concentration profile of the resistive breakdown region are determined so that a depth of an electric neutral region as the region in the resistive breakdown region not depleted at application of the drain bias when junction breakdown occurs in the drain region may be smaller than a depth of an electric neutral region of the drain region.

5. The transistor-type protection device according to claim 4, wherein edge locations of the drain region and the resistive breakdown region are aligned on a well surface opposite to the gate electrode.

6. The transistor-type protection device according to claim 1, wherein one or more breakdown-facilitated regions including the first-conductivity-type semiconductor in contact with or close to a part of the resistive breakdown region, the breakdown-facilitated regions mutually discretely provided.

7. The transistor-type protection device according to claim 1, wherein a well contact region including the first-conductivity-type semiconductor at higher concentration than that of the well is formed in contact with the well at an opposite side to the gate electrode in the source region.

8. A transistor-type protection device comprising:
a semiconductor substrate;
a well including a first-conductivity-type semiconductor formed in the semiconductor substrate;
a source region including a second-conductivity-type semiconductor formed in the well;
a gate electrode formed above the well via a gate insulating film at one side of the source region;
a drain region including the second-conductivity-type semiconductor formed within the well apart at one side of the gate electrode;
a resistive breakdown region including a second-conductivity-type semiconductor region in contact with the drain region at a predetermined distance apart from the well part immediately below the gate electrode; and
a breakdown-facilitated region including the first-conductivity-type semiconductor in contact with or close to a part of the resistive breakdown region.

9. A transistor-type protection device comprising:
a semiconductor substrate;
a base region including a first-conductivity-type semiconductor formed in the semiconductor substrate;
an emitter region including a second-conductivity-type semiconductor formed within the base region;
a collector region including the second-conductivity-type semiconductor formed within the base region apart from the emitter region; and
a resistive breakdown region including a second-conductivity-type semiconductor region formed in contact with the collector region within the base region at a predetermined distance apart from the emitter region,
wherein a metallurgical junction form and a impurity concentration profile of the resistive breakdown region are determined so that a region not depleted at application of a collector voltage when junction breakdown occurs in the collector region or the resistive breakdown region may remain in the resistive breakdown region.

10. A semiconductor integrated circuit comprising:
a circuit connected to first wiring and second wiring; and
a transistor-type protection device turned on when a potential difference between the first wiring and the second wiring becomes equal to or more than a fixed value and protects the circuit,
the transistor-type protection device including
a semiconductor substrate,
a well including a first-conductivity-type semiconductor formed in the semiconductor substrate,
a source region including a second-conductivity-type semiconductor formed in the well,
a gate electrode formed above the well via a gate insulating film at one side of the source region,
a drain region including the second-conductivity-type semiconductor formed within the well apart at one side of the gate electrode, and
a resistive breakdown region including a second-conductivity-type semiconductor region in contact with the drain region at a predetermined distance apart from the well part immediately below the gate electrode,
wherein a metallurgical junction form and a impurity concentration profile of the resistive breakdown region are determined so that a region not depleted at application of a drain bias when junction breakdown occurs in the drain region or the resistive breakdown region may remain in the resistive breakdown region.

11. A semiconductor integrated circuit comprising:
a circuit connected to first wiring and second wiring; and
a transistor-type protection device turned on when a potential difference between the first wiring and the second wiring becomes equal to or more than a fixed value and protects the circuit,
the transistor-type protection device including
a semiconductor substrate,
a well including a first-conductivity-type semiconductor formed in the semiconductor substrate,
a source region including a second-conductivity-type semiconductor formed in the well,
a gate electrode formed above the well via a gate insulating film at one side of the source region,
a drain region including the second-conductivity-type semiconductor formed within the well apart at one side of the gate electrode,
a resistive breakdown region including a second-conductivity-type semiconductor region in contact with the drain region at a predetermined distance apart from the well part immediately below the gate electrode, and
a breakdown-facilitated region including the first-conductivity-type semiconductor in contact with or close to a part of the resistive breakdown region.

12. A semiconductor integrated circuit comprising:
a circuit connected to first wiring and second wiring; and
a transistor-type protection device turned on when a potential difference between the first wiring and the second wiring becomes equal to or more than a fixed value and protects the circuit,
the transistor-type protection device including
a semiconductor substrate,
a base region including a first-conductivity-type semiconductor formed in the semiconductor substrate,
an emitter region including a second-conductivity-type semiconductor formed within the base region,
a collector region including the second-conductivity-type semiconductor formed within the base region apart from the emitter region, and
a resistive breakdown region including a second-conductivity-type semiconductor region formed in contact with the collector region within the base region at a predetermined distance apart from the emitter region,
wherein a metallurgical junction form and a impurity concentration profile of the resistive breakdown region are determined so that a region not depleted at application of a collector voltage when junction breakdown occurs in the collector region or the resistive breakdown region may remain in the resistive breakdown region.

13. A manufacturing method of a semiconductor integrated circuit comprising the steps of:
forming a first well in a circuit region of a semiconductor substrate and forming a first-conductivity-type second well in a protection device region; and
forming various impurity regions within the first well and the second well,
the step of forming various impurity regions including
a first step of forming a resistive breakdown region including a second-conductivity-type semiconductor in the second well, and
a second step of simultaneously forming a first second-conductivity-type high-concentration impurity region in contact with the resistive breakdown region and a second second-conductivity-type high-concentration impurity region at a predetermined distance apart from an end of the resistive breakdown region,
wherein, at the first step, another impurity region including the second-conductivity-type semiconductor is formed within the first well simultaneously with the resistive breakdown region is formed within the second well under a condition that a metallurgical junction form and a impurity concentration profile with which a region not depleted remains in the resistive breakdown region when a voltage at which junction breakdown occurs in the first high-concentration impurity region or the resistive breakdown region is applied to the first high-concentration impurity region with reference to potentials of the second high-concentration impurity region and the second well.

14. The manufacturing method of a semiconductor integrated circuit according to claim 13, wherein the other impurity region is an extension region reaching a first well part below a gate electrode from a drain region of an insulating gate transistor formed in the first well or a halo region in contact with a well depth side of the extension region.

15. The manufacturing method of a semiconductor integrated circuit according to claim 13, wherein the other impurity region is a channel stopper region formed in the first well immediately below a device isolation insulating film, the device isolation insulating film insulating and isolating an insulating gate transistor formed in the first well from other devices.

16. The manufacturing method of a semiconductor integrated circuit according to claim 13, wherein the other impurity region is a resistance region determining a resistance value of a diffusion layer resistance device formed in the first well.

17. A manufacturing method of a semiconductor integrated circuit comprising the steps of:
forming a first well in a circuit region of a semiconductor substrate and forming a first-conductivity-type second well in a protection device region; and
forming various impurity regions within the first well and the second well,
the step of forming various impurity regions including
a first step of forming a resistive breakdown region including a second-conductivity-type semiconductor in the second well,
a second step of forming a breakdown-facilitated region in contact with or close to the resistive breakdown region from a well depth side, and
a third step of simultaneously forming a first second-conductivity-type high-concentration impurity region in contact with the resistive breakdown region and a second second-conductivity-type high-concentration impurity region at a predetermined distance apart from an end of the resistive breakdown region,
wherein, at the second step, another impurity region including the second-conductivity-type semiconductor is formed within the first well simultaneously with the resistive breakdown region is formed within the second well so that a sheet resistance of a region not depleted left in the resistive breakdown region when a voltage at which junction breakdown occurs in the first high-concentration impurity region or the resistive breakdown region is applied to the first high-concentration impurity region with reference to potentials of the second high-concentration impurity region and the second well may take a predetermined value.
